(19) United States
(12) Patent Application Publication
(10) Pub. No.: US 2025/0240966 A1
(43) Pub. Date: Jul. 24, 2025

(54) INTEGRATED CIRCUIT MEMORY DEVICES THAT SUPPORT CHIP-SCALE PACKAGING

(71) Applicant: Samsung Electronics Co., Ltd., Suwon-si (KR)

(72) Inventors: Kohji Kanamori, Suwon-si (KR); Sanghun Chun, Suwon-si (KR); Seogoo Kang, Suwon-si (KR); Kyungdong Kim, Suwon-si (KR); Jeehoon Han, Suwon-si (KR)

(21) Appl. No.: 18/966,513

(22) Filed: Dec. 3, 2024

(30) Foreign Application Priority Data
Jan. 24, 2024 (KR) 10-2024-0010946

(51) Int. Cl. H10B 43/30; H01L 23/522; H01L 23/528; H10B 43/10

(52) U.S. Cl. CPC H10B 43/30; H01L 23/5226; H01L 23/5283; H10B 43/10

(57) ABSTRACT

An integrated circuit device includes a lower circuit pattern on a substrate, a bit line on the lower circuit pattern, a gate electrode structure on the bit line, and a memory channel structure extending through the gate electrode structure. The memory channel structure includes a first capping pattern on the bit line, a channel on the first capping pattern, a second capping pattern on the channel, and a charge storage structure at outer sidewalls of the first capping pattern, the channel and the second capping pattern. A common source plate (CSP) is provided on the memory channel structure.

### REFERENCE TO PRIORITY APPLICATION

This application claims priority under 35 U.S.C. § 119 to Korean Patent Application No. 10-2024-0010946, filed Jan. 24, 2024, the disclosure of which is hereby incorporated herein by reference.

### TECHNICAL FIELD

The inventive concepts relate to integrated circuit devices and, more particularly, to integrated circuit memory devices that are vertically integrated and compatible with chip-scale packaging.

### BACKGROUND

In an electronic system requiring data storage, a high-capacity semiconductor memory device that may store high capacity data is desirable. Thus, a method of increasing the data storage capacity of the semiconductor memory device has been studied. For example, a semiconductor memory device including memory cells that may be 3-dimensionally stacked has been suggested.

Research on a method for highly integrating memory cells in the semiconductor memory device is required.

### SUMMARY

Example embodiments provide an integrated circuit semiconductor device having improved electrical characteristics.

According to example embodiments, there is provided an integrated circuit semiconductor device. The semiconductor device may include a lower circuit pattern, a bit line structure, a gate electrode structure, a memory channel structure and a common source plate (CSP). The lower circuit pattern may be disposed on a substrate. The bit line may be disposed on the lower circuit pattern. The gate electrode structure may be disposed on the bit line and include gate electrodes spaced apart from each other in a first direction wherein length in a second direction of the gate electrodes may gradually decrease from a bottom to a top along the first direction, with the first direction being substantially perpendicular to an upper surface of the substrate, and the second direction being substantially parallel to the upper surface of the substrate. In addition, the memory channel structure may extend through the gate electrode structure and include a first capping pattern on the bit line, a channel on the first capping pattern, a second capping pattern on the channel and a charge storage structure at outer sidewalls of the first capping pattern, the channel and the second capping pattern. The CSP may be disposed on the memory channel structure.

According to example embodiments, there is provided an integrated circuit semiconductor device. The semiconductor device may include a lower circuit pattern, a gate electrode structure, an insulation pattern structure, a memory channel structure, a through via and a common source plate (CSP). The lower circuit pattern may be disposed on a substrate. The gate electrode structure may include gate electrodes spaced apart from each other in a first direction, wherein length in a second direction of the gate electrodes may gradually decrease from a bottom to a top along the first direction, the first direction being substantially perpendicular to an upper surface of the substrate, and the second direction being substantially parallel to the upper surface of the substrate. The insulation pattern structure may extend through the gate electrode structure, include first insulation patterns respectively disposed at heights corresponding to the gate electrodes and second insulation patterns disposed between neighboring ones in the first direction of the first insulation patterns. The memory channel structure may extend through the gate electrode structure, and include a first capping pattern on the bit line, a channel on the first capping pattern, a second capping pattern on the channel and a charge storage structure at outer sidewalls of the first capping pattern, the channel and the second capping pattern. The through via may extend through the insulation pattern structure. The CSP may be disposed on the memory channel structure.

According to further embodiments, there is provided an integrated circuit semiconductor device. The semiconductor device may include a lower circuit pattern, a first bonding structure, a first bit line, a first gate electrode structure, a first memory channel structure, a first common source plate (CSP), a second bonding structure, a second CSP, a second gate electrode structure, a second memory channel structure and a second bit line. The lower circuit pattern may extend on a substrate. The first bonding structure may be disposed on the lower circuit pattern. The first bit line may be disposed on the first bonding structure. The first gate electrode structure may include first gate electrodes spaced apart from each other in a first direction. In addition, a length in a second direction of the first gate electrodes may gradually decrease from a bottom to a top along the first direction, the first direction being substantially perpendicular to an upper surface of the substrate, and the second direction being substantially parallel to the upper surface of the substrate. The first memory channel structure may extend through the first gate electrode structure, and include a first capping pattern on the first bit line, a first channel on the first capping pattern, a second capping pattern on the first channel and a first charge storage structure at outer sidewalls of the first capping pattern, the first channel and the second capping pattern. The first CSP may be disposed on the first memory channel structure. The second bonding structure may be disposed on the first CSP. The second CSP may be disposed on the second bonding structure. The second gate electrode structure may include second gate electrodes spaced apart from each other in the first direction, wherein length in the second direction of the second gate electrodes may gradually increase from a bottom to a top along the first direction. The second memory channel structure may extend through the second gate electrode structure and include a third capping pattern, a second channel on the third capping pattern, a fourth capping pattern on the second channel and a second charge storage structure at outer sidewalls of the third capping pattern, the second channel and the fourth capping pattern. The second bit line may be disposed on the second memory channel structure.

### BRIEF DESCRIPTION OF THE DRAWINGS

FIGS. 1 to 5 are plan views and cross-sectional views illustrating an integrated circuit semiconductor device in accordance with example embodiments.

FIGS. 6 to 55 are plan views and cross-sectional views illustrating a method of manufacturing an integrated circuit semiconductor device in accordance with example embodiments.

FIG. 56 is a cross-sectional view illustrating an integrated circuit semiconductor device in accordance with example embodiments.

FIG. 57 is a cross-sectional view illustrating an integrated circuit semiconductor device in accordance with example embodiments.

FIGS. 58 to 59 are cross-sectional views illustrating a method of manufacturing an integrated circuit semiconductor device in accordance with example embodiments.

FIG. 60 is a cross-sectional view illustrating an integrated circuit semiconductor device in accordance with example embodiments.

### DETAILED DESCRIPTION

The above and other aspects and features of the capacitor structures and the methods of manufacturing the same, the semiconductor devices including the capacitor structures and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, a vertical direction substantially perpendicular to an upper surface of a substrate may be referred to as a first direction D1, and two directions crossing each other among horizontal directions substantially parallel to the upper surface of the substrate may be referred to as second and third directions D2 and D3, respectively. In example embodiments, the second and third directions D2 and D3 may be substantially perpendicular to each other.

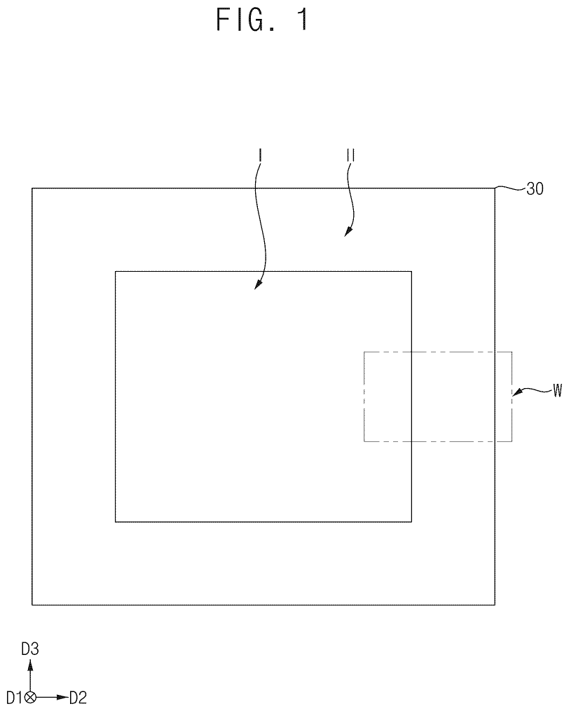

FIGS. 1 to 5 are plan views and cross-sectional views illustrating an integrated circuit semiconductor device in accordance with example embodiments.

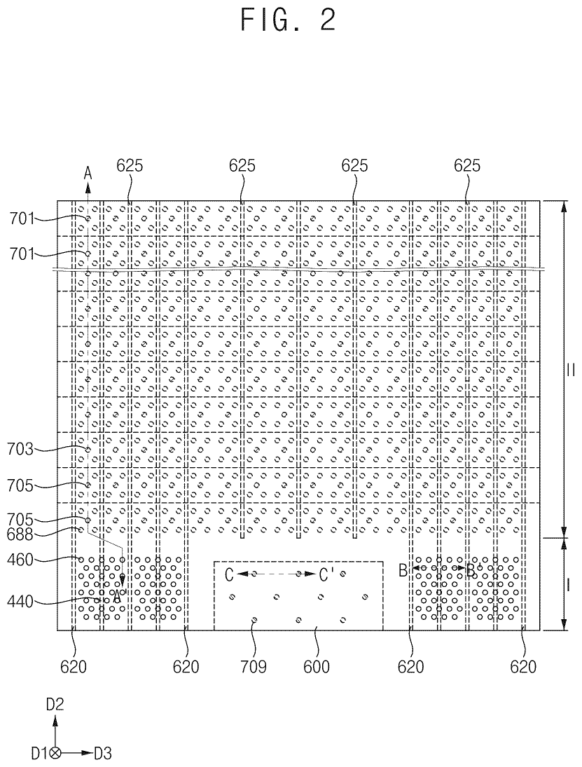

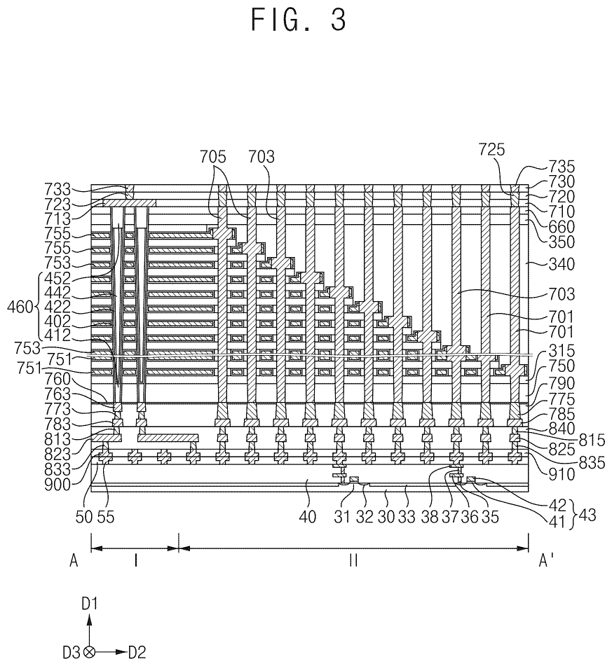

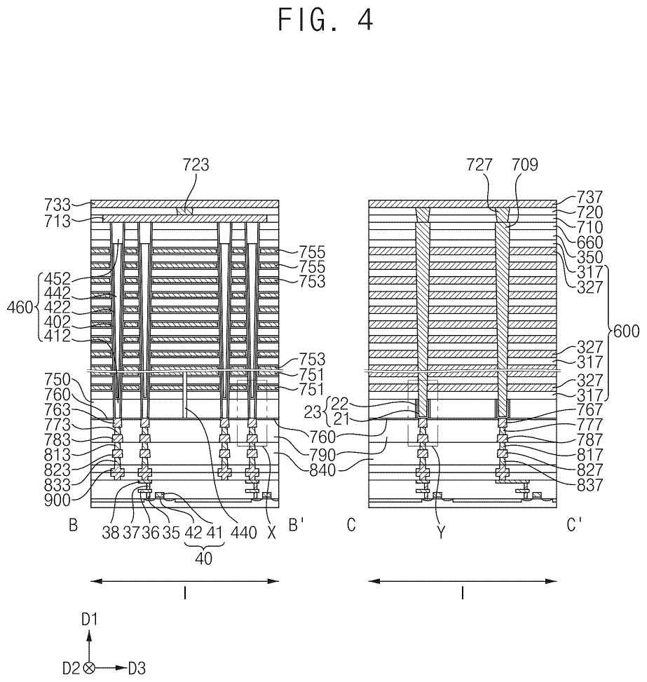

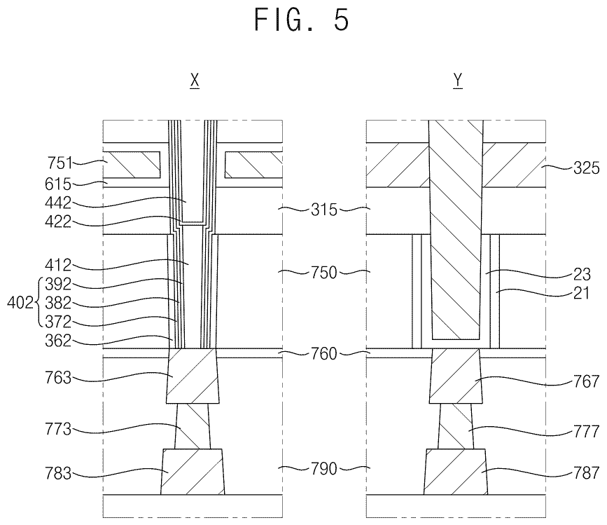

Specifically, FIG. 1 is the plan view, and FIGS. 2 to 5 are drawings about region W of FIG. 1. FIG. 2 is the plan view, FIG. 3 is a cross-sectional view taken along line A-A′ of FIG. 2, FIG. 4 includes cross-sectional views taken along lines B-B′ and C-C′ of FIG. 2, and FIG. 5 includes enlarged cross-sectional views of region X and region Y of FIG. 4.

FIG. 2 does not show some of upper wirings, upper vias and upper contact plugs in order to avoid the complexity of the drawing.

Referring to FIGS. 1 to 5, the integrated circuit semiconductor device may include a lower circuit pattern, an eleventh insulating interlayer 40, a first bonding structure and a first structure on a third substrate 30.

The first structure may include a fourth wiring 783, an etch stop layer 760, a landing structure 23, a gate electrode structure, first to third division patterns 620, 625 and 440, a memory channel structure 460, a support structure 688, first to third upper contact plugs 701, 703 and 705, a through via 709 and a common source plate (CSP) 713. The first structure may also include first to fourteenth vias 723, 725, 727, 763, 773, 775, 767, 777, 813, 833, 815, 835, 817 and 837, first to third, and fifth to ninth wirings 733, 735, 737, 785, 787, 823, 825 and 827, first to third, and fifth to tenth insulating interlayers 340, 350, 660, 710, 720, 730, 750, 790 and 840.

The third substrate 30 may include a semiconductor material, e.g., silicon, germanium, silicon-germanium, etc., or a III-V group compound semiconductor, e.g., GaP, GaAs, GaSb, etc. In some example embodiments, the third substrate 30 may be a silicon-on-insulator (SOI) substrate or a germanium-on-insulator (GOI) substrate.

The third substrate 30 may include a first region I and a second region Il surrounding the first region I. In example embodiments, the first region I may be a cell array region, and the second region II may be a pad region or an extension region. The first and second regions I and II of the third substrate 30 may collectively form a cell region.

Particularly, memory cells each of which includes a gate electrode, a channel and a charge storage structure may be formed on the first region I of the third substrate 30, and upper contact plugs for transferring electrical signals to the memory cells and pads of the gate electrodes contacting the upper contact plugs may be formed on the second region II of the third substrate 30. FIG. 1 shows that the second region II of the third substrate 30 entirely surrounds the first region I of the third substrate 30, however, the inventive concept may not be limited thereto, and for example, the second region II of the third substrate 30 may be formed only at opposite sides of the first region I of the third substrate 30 in the second direction D2.

The third substrate 30 may further include a third region surrounding the second region II, and upper circuit patterns for applying electrical signals to the memory cells through the upper contact plugs may be formed on the third region of the third substrate 30.

The third substrate 30 may include a field region on which an isolation pattern 33 is formed, and an active region 31 on which no isolation pattern 33 is formed. The isolation pattern 33 may include an oxide, e.g., silicon oxide.

In example embodiments, the integrated circuit semiconductor device may have a cell over periphery (COP) structure. That is, the lower circuit pattern may be disposed on the third substrate 30, and the memory cells, the upper contact plugs and the upper circuit pattern may be disposed over the lower circuit pattern. The lower circuit pattern may include, e.g., a transistor, a lower contact plug 35, first and second lower wirings 36 and 38, a lower via 37, etc.

The transistor may include a lower gate structure 43 disposed on the third substrate 30, and an impurity region 32 that may serve as a source/drain and be disposed at an upper portion of the active region 31 adjacent to the lower gate structure 43.

The lower gate structure 43 may include a lower gate insulation pattern 41 and a lower gate electrode 42 sequentially stacked on the third substrate 30.

The lower contact plug 35 may contact the impurity region 32. A lower contact plug contacting the lower gate electrode 42 may be additionally formed.

The first lower wiring 36, the lower via 37 and the second lower wiring 38 may be sequentially stacked on the lower contact plug 35.

The eleventh insulating interlayer 40 may cover the transistor, the lower contact plug 35, the first and second lower wirings 36 and 38 and the lower via 37.

The first bonding structure may be formed on the eleventh insulating interlayer 40 and the lower circuit pattern. The first bonding structure may include first and second bonding layers 910 and 50 and first and second bonding patterns 900 and 55.

The second bonding layer 50 may be formed on the eleventh insulating interlayer 40, and the second bonding pattern 55 may extend through the second bonding layer 50 to contact one of lower wirings or lower vias of the lower circuit pattern. In example embodiments, a plurality of second bonding patterns 55 may be spaced apart from each other in the second and third directions D2 and D2.

The first bonding layer 910 may be formed on the second bonding layer 50, and the first bonding pattern 900 may extend through the first bonding layer 910 to contact the second bonding pattern 55. In example embodiments, a plurality of first bonding patterns 900 may be spaced apart from each other in the second and third directions D2 and D3 corresponding to the second bonding pattern 55.

In example embodiments, the first bonding pattern 900 may have a “ [symbol] ” shape in cross-section, and the second bonding pattern 55 may have a “ [symbol] ” shape in cross-section.

In example embodiments, each of the first and second bonding layers 910 and 50 may include, e.g., silicon carbonitride (SiCN), and each of the first and second bonding patterns 900 and 55 may include a metal, e.g., copper (Cu).

The tenth via 833, the seventh wiring 823 and the ninth via 813 may be sequentially stacked on a corresponding one of the first bonding patterns 900. The twelfth via 835, the eighth wiring 825 and the eleventh via 815 may be sequentially stacked on a corresponding one of the first bonding patterns 900. The fourteenth via 837, the ninth wiring 827 and the thirteenth via 817 may be sequentially stacked on a corresponding one of the first bonding patterns 900.

The tenth insulating interlayer 840 may cover the ninth to fourteenth vias 813, 833, 815, 835, 817 and 837 and the seventh to ninth wirings 823, 825 and 827.

The fourth wiring 783 and the fifth and fourth vias 773 and 763 may be sequentially stacked on the ninth via 813. The fourth wiring 783 may be electrically connected to the transistor through the ninth via 813, the seventh wiring 823, the tenth via 833 and corresponding ones of the first and second bonding patterns 900 and 55. The fourth wiring 783 may serve as a bit line.

In example embodiments, the fourth wiring 783 may extend in the third direction D3 on the first region I of the third substrate 30, and a plurality of fourth wirings may be spaced apart from each other in the second direction D2.

In example embodiments, a width in the horizontal direction of an upper surface of the fourth via 763 may be greater than a width in the horizontal direction of a lower surface of the first capping pattern 412. When the fourth via 763 is not formed so that the fifth via 773 is in direct contact with the first capping pattern 412, a width in the horizontal direction of an upper surface of the fifth via 773 may be greater that the width in the horizontal direction of the lower surface of the first capping pattern 412.

The fifth wiring 785 and the sixth via 775 may be sequentially stacked on the eleventh via 815. The fifth wiring 785 may be electrically connected to the transistor through the eleventh via 815, the eighth wiring 825, the twelfth via 835 and corresponding ones of the first and second bonding patterns 900 and 55.

The sixth wiring 787 and the eighth and seventh vias 777 and 767 may be sequentially stacked on the thirteenth via 817. The sixth wiring 787 may be electrically connected to the transistor through the thirteenth via 817, the ninth wiring 827, the fourteenth via 837 and corresponding ones of the first and second bonding patterns 900 and 55.

In example embodiments, a width in the horizontal direction of an upper surface of the seventh via 767 may be smaller than a width in the horizontal direction of a lower surface of the landing pad 22.

The ninth insulating interlayer 790 may cover the fourth to eighth vias 763, 773, 775, 767 and 777 and the fourth to sixth wirings 783, 785, and 787.

The etch stop layer 760 may be formed on the ninth insulating interlayer 790 and may cover upper sidewalls of the fourth, sixth, and seventh vias 763, 775 and 767. An upper surface of the etch stop layer 760 may be substantially coplanar with an upper surface of each of the fourth, sixth and seventh vias 763, 775 and 767. In example embodiments, the etch stop layer 760 may include a nitride, e.g., silicon nitride.

The eighth insulating interlayer 750 may be formed on the etch stop layer 760.

The gate electrode structure may include a plurality of gate electrodes spaced apart from each other in the first direction D1 on the eighth insulating interlayer 750. Each of the gate electrodes may extend in the second direction D2.

In example embodiments, the gate electrode structure may include first to third gate electrodes 751, 753 and 755 sequentially stacked along the first direction D1. Each of the first and third gate electrodes 751 and 755 may be disposed at one or more layers, and the second gate electrodes 753 may be respectively disposed at a plurality of layers. FIGS, 1 to 6 shows each of the first and third gate electrodes 751 and 755 disposed at two layers, but the concept of the present invention is not limited thereto.

In example embodiments, the first gate electrode 751 may serve as a string select line (SSL), the second gate electrode 753 may serve as a word line, and the third gate electrode 755 may serve as a ground select line (GSL).

However, the first gate electrodes 751 may be additionally formed at one or more layers below the SSL and/or above the GSL to serve as a GIDL gate electrode enabling body erase by using gate induced drain leakage (GIDL) phenomenon. Some of the second gate electrodes 753 disposed between the SSL and the GSL may serve as a dummy word line.

Each of the first to third gate electrodes 751, 753 and 755 may include a gate conductive pattern and a gate barrier pattern covering a surface of the gate conductive pattern. The gate conductive pattern may include a metal having a low resistance, e.g., tungsten, titanium, tantalum, platinum, etc., and the gate barrier pattern may include a metal nitride, e.g., titanium nitride, tantalum nitride, etc.

The first insulation pattern 315 may be formed between neighboring ones of the first to third gate electrodes 751, 753 and 755 in the first direction D1, on an upper surface of an uppermost one of the third gate electrodes 755, and between the first gate electrode 751 and the eighth insulating interlayer 750. The first insulation pattern 315 may include an oxide, e.g., silicon oxide.

In example embodiments, the gate electrode structure may have a staircase shape in which lengths in the second direction D2 decreases in a stepwise manner in the first direction D1 from a lowermost level toward an uppermost level, and may include steps arranged in the second direction D2 on the second region II of the third substrate 30. In some embodiments, the gate electrode structure may further include steps arranged in the third direction D3 on the second region II of the third substrate 30.

Hereinafter, a portion of the gate electrodes corresponding to the steps of the gate electrode structure, that is, an end portion of each of the gate electrodes that may not overlapped by upper ones of the gate electrodes may be referred to as a pad. Thus, the pad of each of the gate electrodes may be disposed on the second region Il of the third substrate 30. In example embodiments, the pad of each of the first to third gate electrodes 751, 753 and 755 may have a greater thickness than other portions of the same gate electrode.

In example embodiments, a plurality of gate electrode structures may be spaced apart from each other in the third direction D3. The first division pattern 620, which may extend in the second direction D2 on the first and second regions I and II of the third substrate 30, may be disposed between and separate the first to third gate electrodes 751, 753 and 755 included in neighboring ones of the gate structures in the third direction D3. In example embodiments, the first division pattern 620 may extend through the first to third insulating interlayers 340, 350 and 660, the first to third gate electrodes 751, 753 and 755 and the eighth insulating interlayer 750.

In example embodiments, each of the gate electrode structures separated by the first division patterns 620 and the memory channel structures 460 extending through a corresponding one of the gate electrode structures may collectively form a memory block. A plurality of memory blocks may be disposed in the third direction D3.

However, one of the memory blocks on which the memory channel structure 460 is not formed may be referred to as a dummy memory block. Hereinafter, the memory blocks except for the dummy memory block may be referred to as an active memory block. Additionally, a portion of the first region I of the third substrate 30 on which the active memory block is formed may be referred to as an active memory block region, and a portion of the first region I of the third substrate 30 on which the dummy memory block is formed may be referred to as a dummy memory block region.

An insulation pattern structure 600 may extend through a portion of the gate electrode structure on the dummy memory block region of the third substrate 30. The insulation pattern structure 600 may have a shape of a rectangle, an oval, a circle, etc., in a plan view. In example embodiments, the insulation pattern structure 600 may include fourth and fifth insulation patterns 317 and 327 alternately and repeatedly stacked along the first direction D1.

The third division pattern 440 may extend through a lower portion of each of the gate structures on the first and second regions I and II of the third substrate 30, that is, lower two layers at which the first gate electrodes 751 are formed. Accordingly, each of the first gate electrodes 751 may be additionally separated in the third direction D3.

The second division pattern 625 may extend in the second direction D2 through the first to third insulating interlayers 340, 350 and 660, the first to third gate electrodes 751, 753 and 755 and the eighth insulating interlayer 750.

Each of the first to third division patterns 620, 625 and 440 may include, e.g., an oxide such as silicon oxide.

The memory channel structure 460 may be formed on the first region I of the third substrate 30. The memory channel structure 460 may extend through the second and third insulating interlayer 350 and 660, the first to third gate electrodes 751, 753 and 755, the first insulation pattern 315 and the eighth insulating interlayer 750 to contact the upper surface of the fourth via 763.

In example embodiments, the memory channel structure 460 may include a first capping pattern 412, which may be disposed on the fourth via 763, a channel 422, which may be disposed on the first capping pattern 412 and have a shape of a cup, a filling pattern 442, which may fill a space formed by an upper portion of the channel 422 and extend in the first direction D1, a second capping pattern 452 which may be in contact with upper surfaces of the filling pattern 442 and the channel 422, and a charge storage structure 402, which may be disposed at outer sidewalls of the first capping pattern 412, the channel 422 and the second capping pattern 452.

An upper surface of the first capping pattern 412 may be higher than a lower surface of a lowermost one of the first insulation patterns 315, but the concept of the present invention is not limited thereto. That is, the upper surface of the first capping pattern 412 may be lower than the lower surface of the lowermost one of the first insulation patterns 315.

The charge storage structure 402 may include a tunnel insulation pattern 392, a charge storage pattern 382 and a first blocking pattern 372 sequentially stacked in the horizontal direction from the outer sidewall of the channel 422.

In example embodiments, a lower surface of the memory channel structure 460 may be substantially coplanar with the upper surface of the etch stop layer 760.

In example embodiments, a plurality of memory channel structures 460 may be spaced apart from each other in the second and third directions D2 and D3 in each of the active memory blocks on the first region I of the third substrate 30 to form a memory channel structure array.

The CSP 713 may extend through the fifth insulating interlayer 710 and commonly contact upper surfaces of the memory channel structures 460 of each of the active memory blocks. Accordingly, the memory channel structures 460 of each of the active memory blocks may be electrically connected to each other by the CSP 713. Accordingly, a plurality of CSPs 713 may be spaced apart from each other in the third direction D3 corresponding to the active memory blocks.

The channel 422 may include, e.g., undoped polysilicon, the filling pattern 442 may include an oxide, e.g., silicon oxide, and the first and second capping patterns 412 and 452 may include, e.g., polysilicon doped with impurities.

The tunnel insulation pattern 392 and the first blocking pattern 372 may include an oxide, e.g., silicon oxide, and the charge storage pattern 382 may include a nitride, e.g., silicon nitride.

An oxidation pattern 362 may be disposed between a lower sidewall of the memory channel structure 460 and the eighth insulating interlayer 750. The oxidation pattern 362 may include, e.g., silicon oxide.

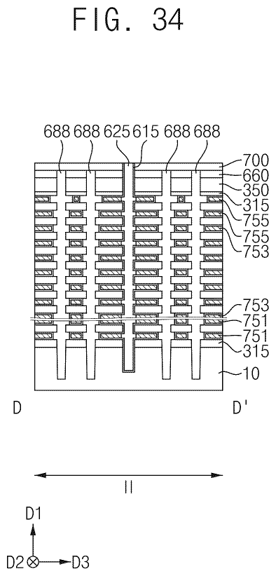

Referring to FIG. 34 together with FIGS. 1 to 5, the support structure 688 may be formed on the second region Il of the third substrate 30, and may extend through the second and third insulating interlayers 350 and 660, the first to third gate electrodes 751, 753 and 755, the first insulation pattern 315 and the eighth insulating interlayer 750. In example embodiments, a plurality of support structures 688 may be spaced apart from each other in the second and third directions D2 and D3 on the second region II of the third substrate 30.

In example embodiments, the support structure 688 may include an extension portion having a pillar shape extending in the first direction D1, and protruding portions protruding in the horizontal direction from a sidewall of the extension portion and spaced apart from each other in the first direction D1. The protruding portions may be respectively formed at portions of the sidewall of the extension portion respectively facing the first to third gate electrodes 751, 753 and 755. In example embodiments, a width in the horizontal direction of an uppermost one of the protruding portions may be greater than a width in the horizontal direction of each of the protruding portions below the uppermost one of the protruding portions. The support structure 688 may include an oxide, e.g., silicon oxide.

The second blocking pattern 615 may cover upper and lower surfaces of each of the first to third gate electrodes 751, 753 and 755, and a sidewall of each of the first to third gate electrodes 751, 753 and 755 that faces the memory channel structure 460, the support structure 688 and the first to third upper contact plugs 701, 703 and 705. The second blocking pattern 615 may include a metal oxide, e.g., aluminum oxide or hafnium oxide.

Each of the first to third upper contact plugs 701, 703 and 705 may extend through the first to third insulating interlayers 340, 350 and 660, the gate electrode structure and the first insulation pattern 315 to contact an upper surface of a corresponding one of the sixth via 775.

Each of the first to third upper contact plugs 701, 703 and 705 may be disposed on the second region II of the third substrate 30.

In example embodiments, the first upper contact plug 701 may extend through the pad of the first gate electrode 751, the second upper contact plug 703 may extend through the pad of the second gate electrode 753 and the first gate electrode 751 there below, and the third upper contact plug 705 may extend through the pad of the third gate electrode 755, and the first and second gate electrodes 751 and 753 there below.

In example embodiments, a fourth insulation pattern 686 may be disposed at each sidewall of the first to third upper contact plugs 701, 703 and 705 respectively facing the first to third gate electrodes 751, 753 and 755. However, the fourth insulation pattern 686 may not be formed at a portion of the sidewall of each of the first to third upper contact plugs 701, 703 and 705 facing a gate electrode including the pad.

In example embodiments, each of the first to third upper contact plugs 701, 703 and 705 may include a protruding portion protruding in the horizontal direction from the portion of the sidewall of each of the first to third upper contact plugs 701, 703 and 705 facing the uppermost one of the gate electrodes. The protruding portion of each of the first to third upper contact plugs 701, 703 and 705 may directly contact the gate electrode including the pad.

The fourth insulation pattern 686 may include an oxide, e.g., silicon oxide.

The through via 709 may be formed on the dummy memory block region of the first region I of the third substrate 30. The through via 709 may extend through the first to third insulating interlayers 340, 350 and 660 to contact an upper surface of the landing structure 23 on the seventh via 767.

The landing structure 23 may include a landing pad 22 and a buffer pattern 21 covering a sidewall of the landing pad 22. The buffer pattern 21 may include an oxide, e.g., silicon oxide, and the landing pad 22 may include a metal, e.g., tungsten.

In example embodiments, the landing structure 23 may have a shape of, e.g., a rectangle, an oval, a circle, etc., in a plan view.

In example embodiments, a plurality of landing structures 23 may be spaced apart from each other in the second and third directions D2 and D3.

In example embodiments, the upper surface of the etch stop layer 760, the lower surface of the memory channel structure 460, a lower surface of each of the first to third upper contact plugs 701, 703 and 705 and the lower surface of the landing structure 23 may be substantially coplanar to each other.

The first to third division patterns 620, 625 and 440, the support structures 688, the first to third upper contact plugs 701, 703 and 705 and the through vias 709 may be formed in various layouts.

The first insulating interlayer 340 may cover sidewalls of the first to third gate electrodes 751, 753 and 755 and the first insulation pattern 315. The second insulating interlayer 350 may be disposed on the first insulating interlayer 340 and the first insulation pattern 315. The third insulating interlayer 660 may be disposed on the second insulating interlayer 350 and cover an upper outer sidewall of the memory channel structure 460, an upper outer sidewall of the support structure 788, an upper outer sidewall of each of the first to third upper contact plugs 701 703 and 705 and an upper outer sidewall of the through via 709. The fifth insulating interlayer 710 may be disposed on the third insulating interlayer 660, the memory channel structure 460, the support structure 788, the first to third upper contact plugs 701, 703 and 705 and the through via 709. The sixth and seventh insulating interlayers 720 and 730 may be sequentially stacked on the fifth insulating interlayer 710.

The first via 723 may extend through the sixth insulating interlayer 720 to contact an upper surface of the CSP 713. The second via 725 may extend through the fifth and sixth insulating interlayers 710 and 720 to contact an upper surface of a corresponding one of the first to third upper contact plugs 701, 703 and 705. The third via 727 may extend through the fifth and sixth insulating interlayers 710 and 720 to contact an upper surface of the through via 709.

The first to third wirings 733, 735 and 737 may extend through the seventh insulating interlayer 730 to contact upper surfaces of the first to third vias 723, 725 and 727, respectively.

In example embodiments, each of the first to fourteenth vias 723, 725, 727, 763, 773, 775, 767, 777, 813, 833, 815, 835, 817 and 837 and each of the first to ninth wirings 733, 735, 737, 783, 785, 787, 823, 825 and 827 may include a conductive pattern and a barrier pattern covering a surface of the conductive pattern. The conductive pattern may include a metal having a low resistance, e.g., tungsten, titanium, tantalum, platinum, etc., and the barrier pattern may include a metal nitride, e.g., titanium nitride, tantalum nitride, etc.

The first to fourteenth vias 723, 725, 727, 763, 773, 775, 767, 777, 813, 833, 815, 835, 817 and 837 and the first to ninth wirings 733, 735, 737, 783, 785, 787, 823, 825 and 827 may be formed in various layouts.

Each of the first to third insulating interlayers 340, 350 and 660 and each of the fifth to eleventh insulating interlayers 710, 720, 730, 750, 790, 840 and 40 may include an oxide, e.g., silicon oxide.

In the integrated circuit semiconductor device, the width in the horizontal direction of the upper surface of the fourth via 763 (if the fourth via 763 is not formed, the upper surface of the fifth via 773) may greater than width in the horizontal direction of the lower surface of the first capping pattern 412. Accordingly, misalignment of the fourth wiring 783 and the fourth via 763 may be reduced.

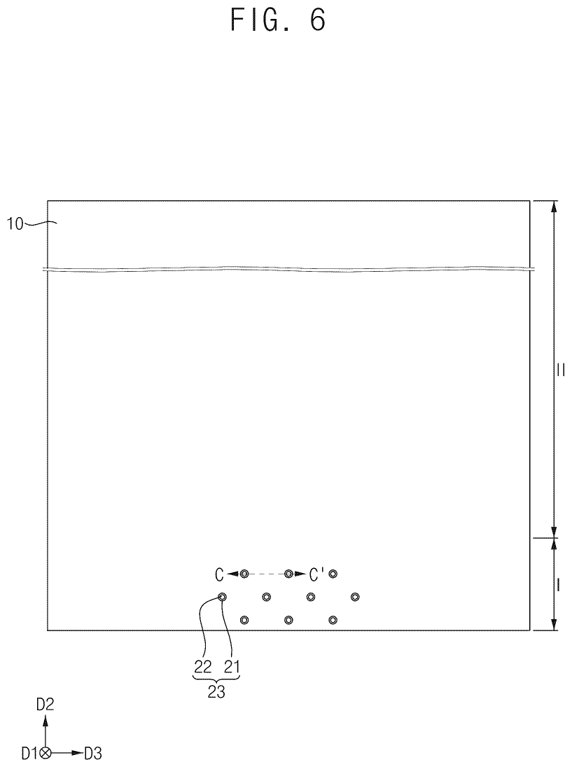

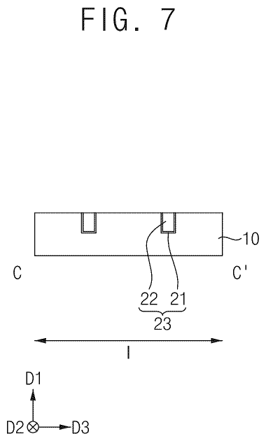

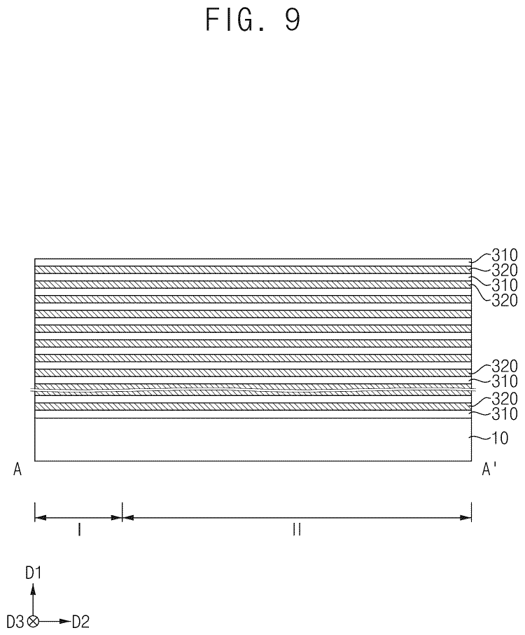

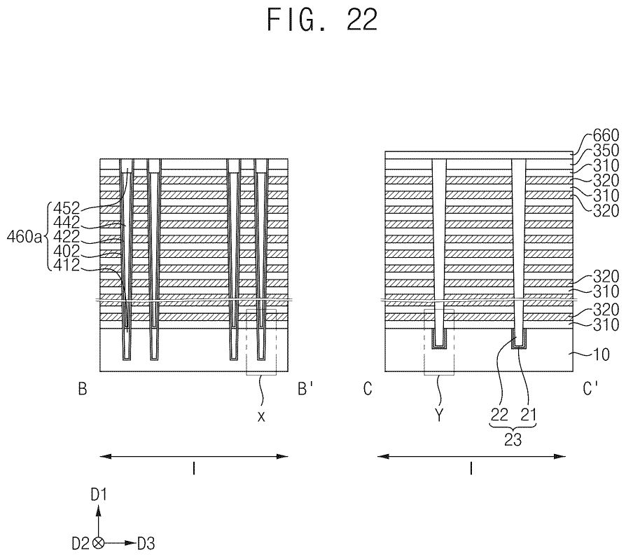

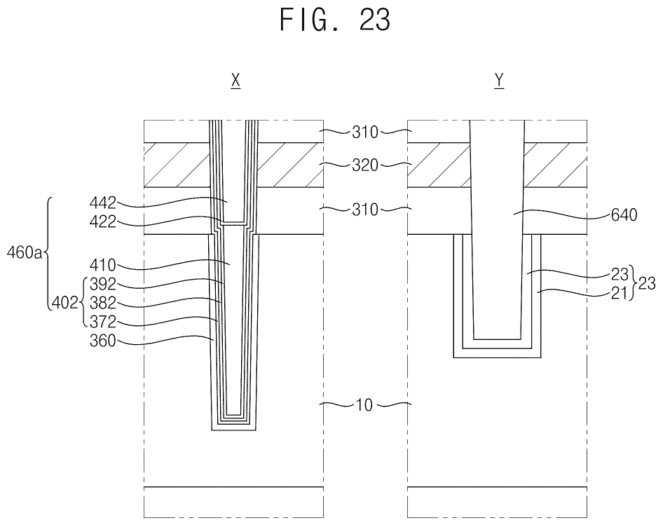

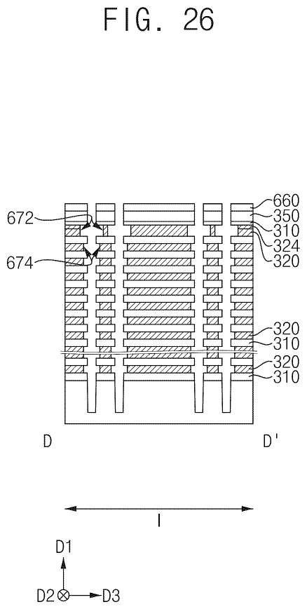

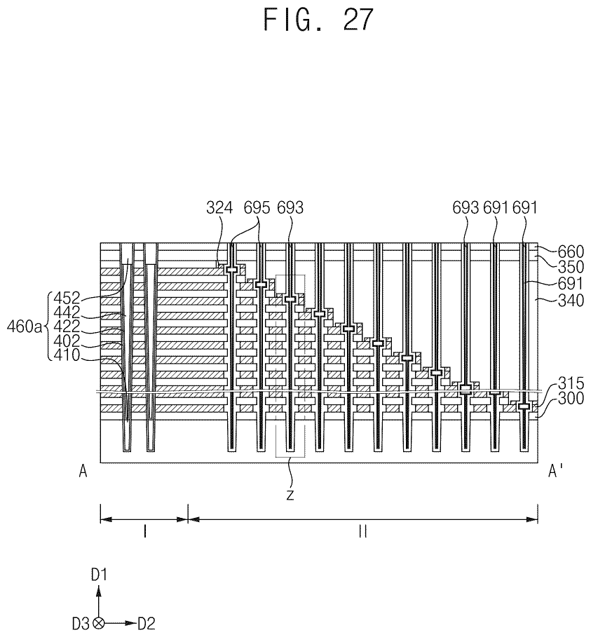

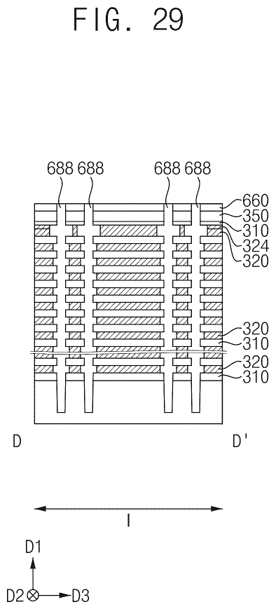

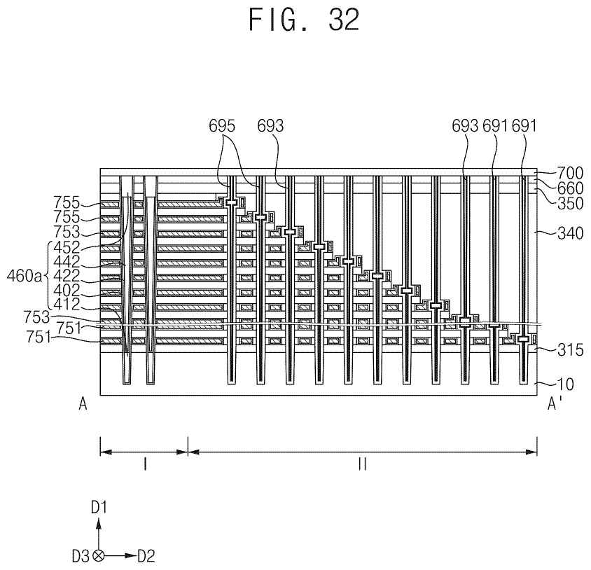

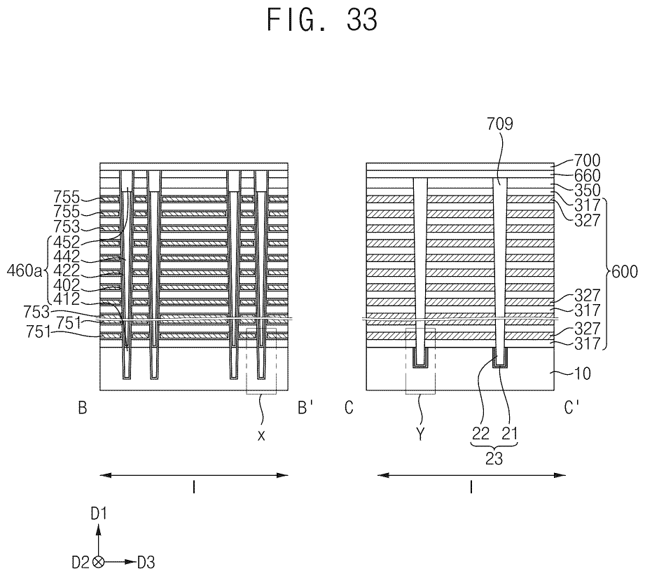

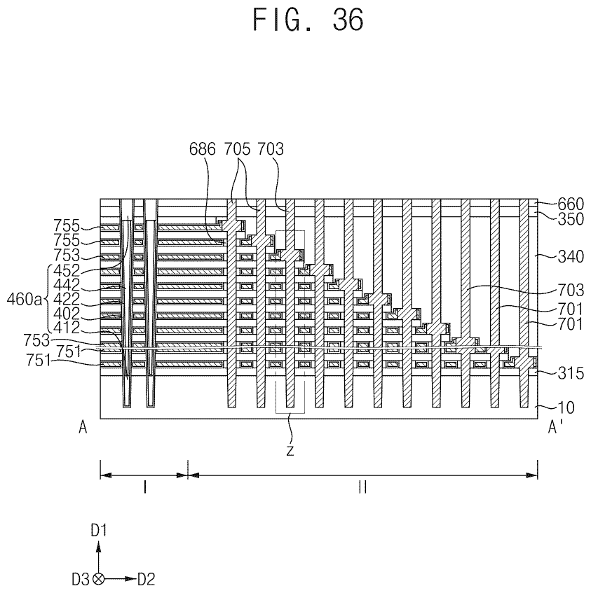

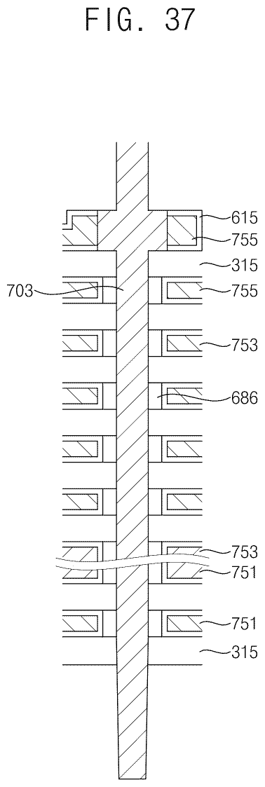

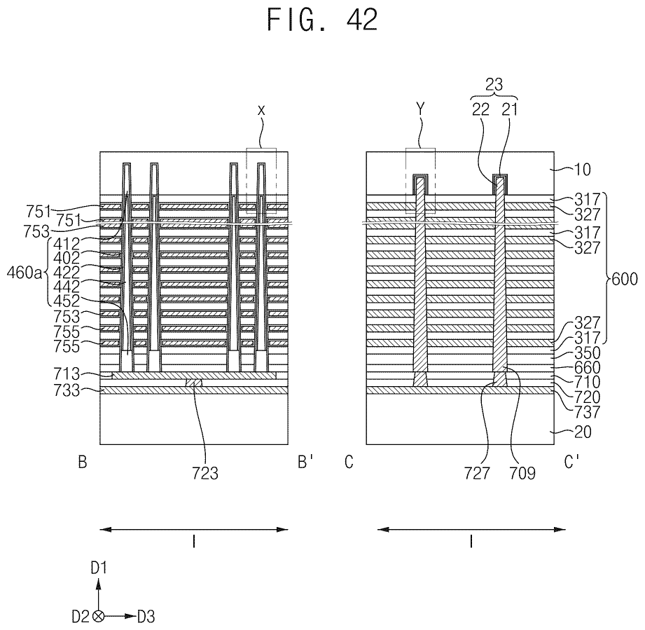

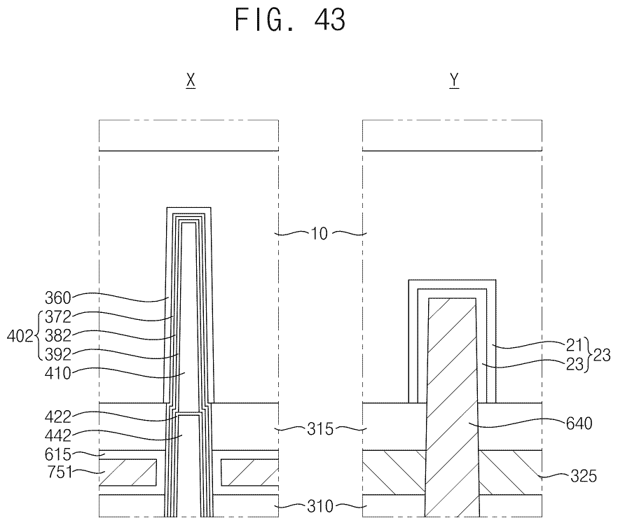

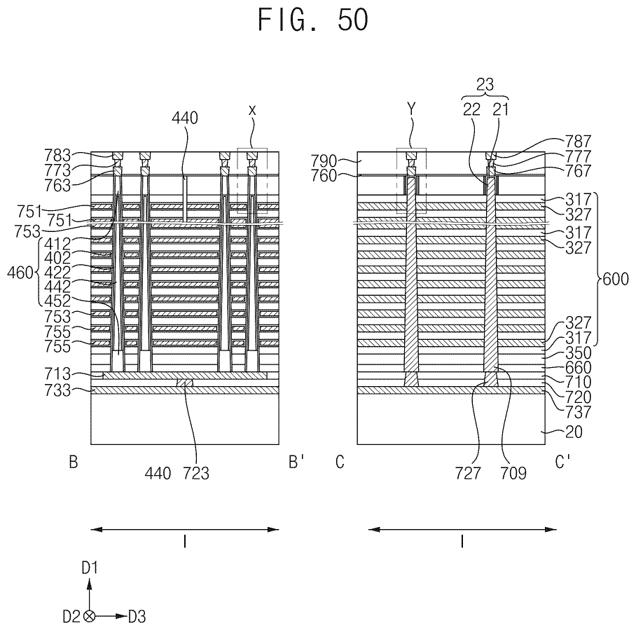

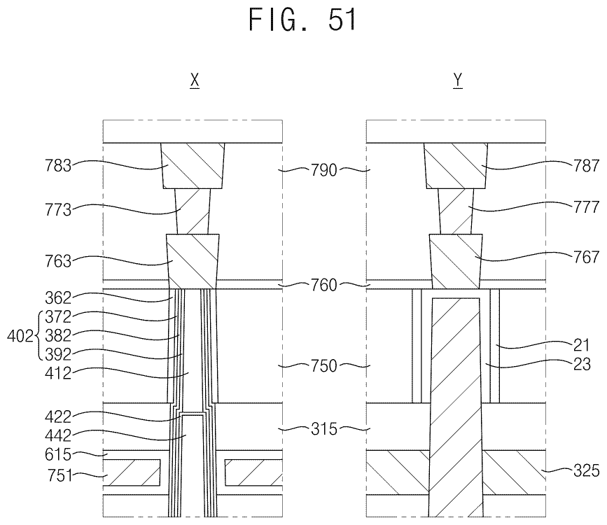

FIGS. 6 to 55 are plan views and cross-sectional views illustrating a method of manufacturing an integrated circuit semiconductor device. Particularly, FIGS. 6, 8, 11, 14, 21, 30-31 and 35 are the plan views, and FIGS. 7, 9-10, 12-13, 15-20, 22-29, 32-34 and 36-55 are the cross-sectional views.

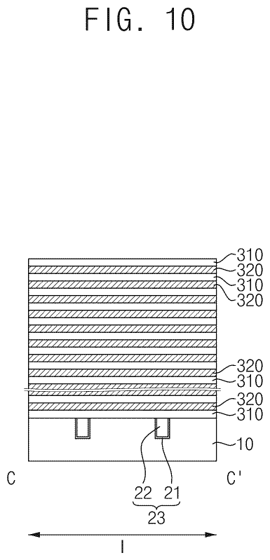

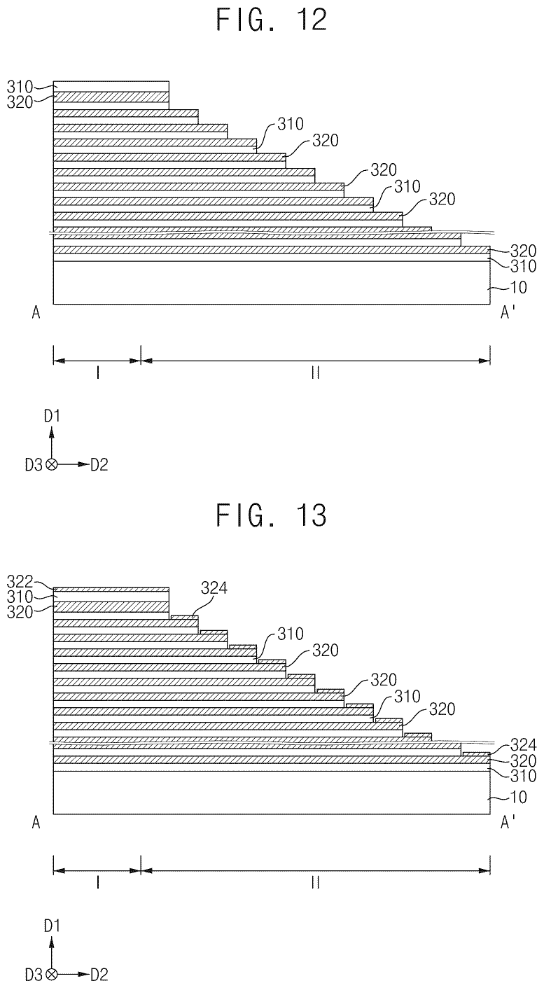

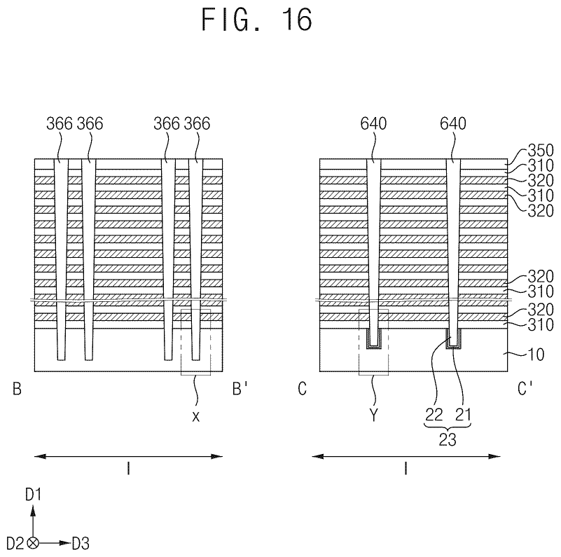

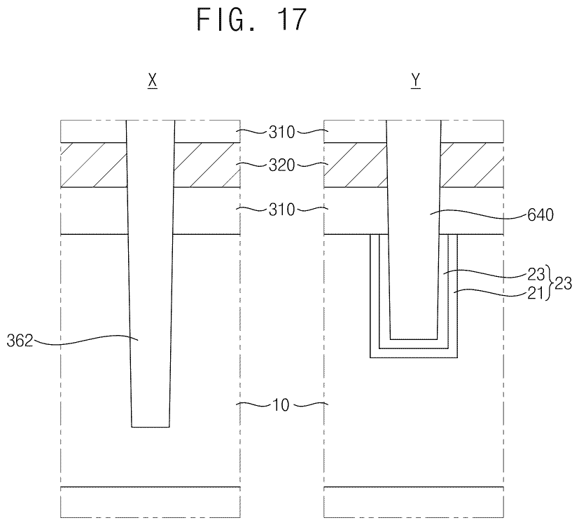

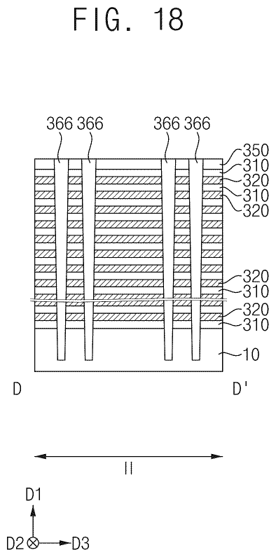

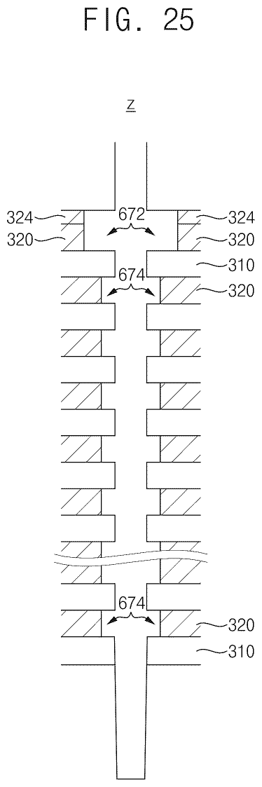

FIGS. 12, 13, 15, 24-25, 27-28, 32, 36-37, 39, 41, 49, 52 and 54-55 are cross-sectional views taken along lines A-A′ of corresponding plan views, respectively, and among these, FIGS. 25, 28 and 37 are enlarged cross-sectional views of region W of corresponding cross-sectional views, respectively. FIGS. 16-17, 19, 20, 22-23, 33, 38, 40, 42-48, 50-51 and 53 include cross-sectional views taken along lines B-B′ and C-C′ of corresponding plan views, respectively, and among these, FIGS. 17, 23, 43-46, 48 and 51 include enlarged cross-sectional views of region X and region Y of corresponding cross-sectional views, respectively. FIGS. 7 and 10 are cross-sectional views taken along lines C-C′ of corresponding plan views, respectively. FIGS. 18, 26, 29 and 34 are cross-sectional views taken along lines D-D′ of corresponding plan views, respectively.

Referring to FIGS. 6 and 7, a landing structure 23 including a landing pad 22 and a buffer pattern 21 covering a lower surface and a sidewall of the landing pad 22 may be formed on the first region I of a first substrate 10.

In example embodiments, the landing structure 23 may have a shape of, e.g., a rectangle, an oval, a circle, etc. in a plan view.

In example embodiments, the landing structure 23 may be formed at a position corresponding to a through via 709, which is formed later. Accordingly, a plurality of landing structures 23 may be formed to be spaced apart from each other in the second and third directions D2 and D3.

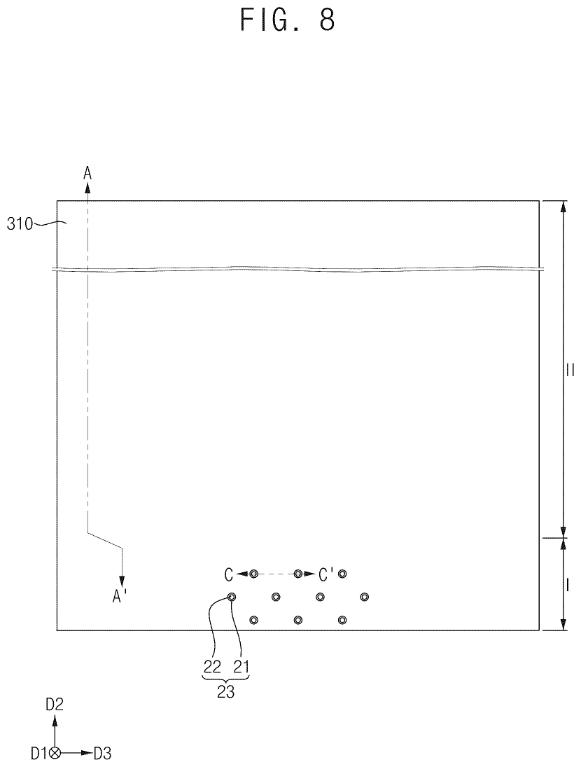

Referring to FIGS. 8 to 10, a first insulation layer 310 and a first sacrificial layer 320 may be alternately and repeatedly stacked in the first direction D1 on the first substrate 10 and the landing structure 23, and thus, a mold layer including the first insulation layers 310 and the first sacrificial layers 320 may be formed. The first insulation layer 310 may include an oxide, e.g., silicon oxide, and the first sacrificial layer 320 may include a material having an etching selectivity with respect to the first insulation layer 310, e.g., a nitride such as silicon nitride.

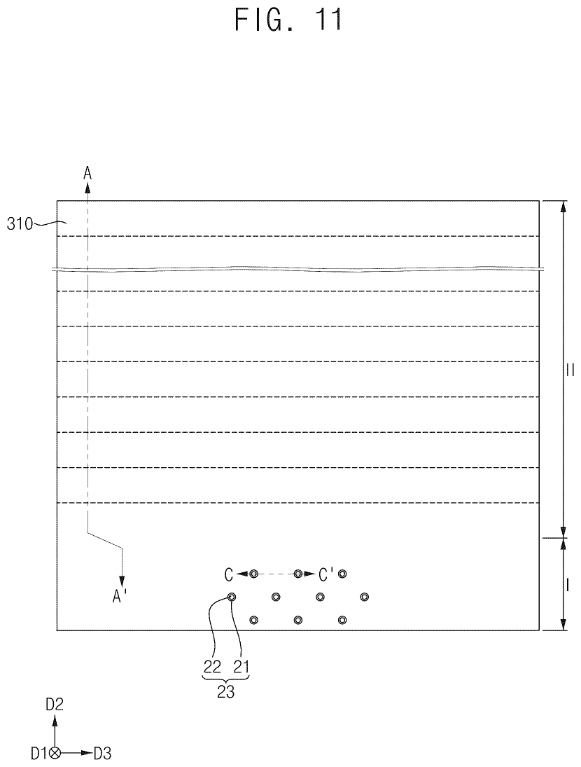

Referring to FIGS. 11 and 12, a photoresist pattern partially covering an uppermost one of the first insulation layers 310 may be formed, and the uppermost one of the first insulation layers 310 and an uppermost one of the first sacrificial layers 320 may be etched using the photoresist pattern as an etching mask. Thus, a portion of one of the first insulation layers 310 directly under the uppermost one of the first sacrificial layers 320 may be exposed.

After performing a trimming process for reducing an area of the photoresist pattern, the uppermost one of the first insulation layers 310, the uppermost one of the first sacrificial layers 320, the exposed one of the first insulation layers 310 and one of the first sacrificial layer 320 directly under the exposed one of the first insulation layers 310 may be etched by an etching process using the reduced photoresist pattern as an etching mask. The trimming process and the etching process may be repeatedly performed to form a mold, which may have a staircase shape and include a plurality of step layers each of which may include one first sacrificial layer 320 and one first insulation layer 310 sequentially stacked.

Hereinafter, the “step layer” may refer to all portions of the first sacrificial layer 320 and the first insulation layer 310 at the same level, which may include an unexposed portion as well as an exposed portion of the first sacrificial layer 320 and the first insulation layer 310, and a “step” may refer to only the exposed portion of the “step layer.” In example embodiments, the steps may be arranged in the second direction D2. Alternatively, the steps may be arranged in the third direction D3.

Each of the steps of the mold may be formed on the second region II of the first substrate 10.

Referring to FIG. 13, an insulation pad layer may be formed, and partially removed to form first and second insulation pads 322 and 324.

In an embodiment, the insulation pad layer may include the same material as the first sacrificial layer 320, however may have an etching rate different from an etching rate of the first sacrificial layer 320.

After forming the insulation pad layer, portions of the insulation pad layer adjacent to sidewalls of the steps of the mold, respectively, may be removed to form the first insulation pad 322 on an upper surface of the uppermost one of first insulation layers 310 and to form the second insulation pad 324 on an upper surface of each of the first sacrificial layers 320 that may form the steps of the mold. In example embodiments, each of the first and second insulation pads 322 and 324 may extend in the third direction D3.

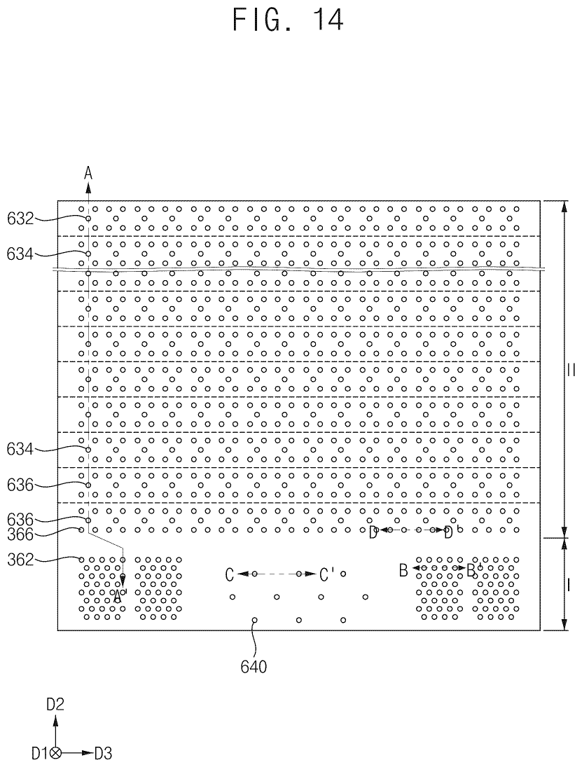

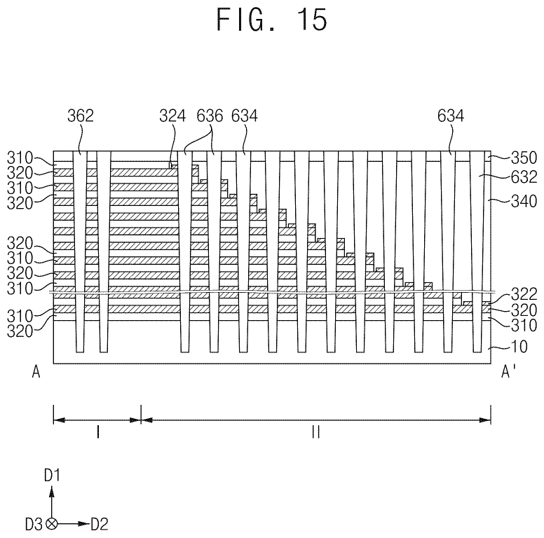

Referring to FIGS. 14 to 18, a first insulating interlayer 340 may be formed to cover the mold and the first and second insulation pads 322 and 324, and may be planarized until an upper surface of one of the first insulation layers 310 on a step layer on which the second insulation pad 324 is formed is exposed.

During the planarization, the first insulation pad 322, and one of the first insulation layers 310 and one of the first sacrificial layers 320 included in an uppermost one of the step layers in the mold may be removed, and a sidewall of the mold may be covered by the first insulating interlayer 340.

A second insulating interlayer 350 may be formed on upper surfaces of the mold and the first insulating interlayer 340.

An etching process may be performed to form a first hole extending in the first direction D1 through the second insulating interlayer 350, the mold and an upper portion of the first substrate 10 on the first region I of the first substrate 10, and a second hole extending in the first direction D1 through the first and second insulating interlayers 340 and 350, a portion of the mold and an upper portion of the first substrate 10 on the second region II of the first substrate 10. In example embodiments, a plurality of first holes may be spaced apart from each other in the second and third directions D2 and D3 on the first region I of the first substrate 10, and a plurality of second holes may be spaced apart from each other in the second and third directions D2 and D3 on the second region II of the first substrate 10.

Additionally, third to fifth holes extending in the first direction D1 through the first and second insulating interlayers 340 and 350, the mold and an upper portion of the first substrate 10 may be formed on the second region II of the first substrate 10. In example embodiments, each of the third to fifth holes may be formed in a region defined by the second holes adjacent to each other in a plan view.

A sixth hole extending in the first direction D1 through the second insulating interlayer 350 and the mold may be formed to expose an upper surface of the landing pad 22 on the first region I of the third substrate 30. In example embodiments, a plurality of sixth holes may be spaced apart from each other in the first and second direction D1 and D2 corresponding to the landing structure 23.

In example embodiments, the first to sixth holes may be simultaneously formed by a single etching process, or may be sequentially formed by independent processes.

Second to seventh sacrificial patterns 362, 366, 632, 634, 636 and 640 may be formed in the first to sixth holes, respectively.

The second to seventh sacrificial patterns 362, 366, 632, 634, 636 and 640 may be formed by forming a second sacrificial layer on the second insulating interlayer 350 to fill the first to sixth holes, and planarizing the second sacrificial layer until an upper surface of the second insulating interlayer 350 is exposed.

In an embodiment, the second sacrificial layer may include, e.g., an insulating material containing carbon, a metal, undoped polysilicon, etc.

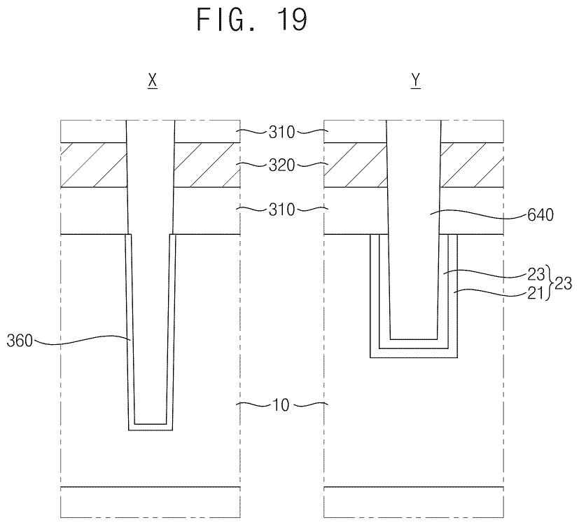

Referring to FIG. 19, a third insulating interlayer 660 may be formed on the second insulating interlayer 350 and the second to seventh sacrificial patterns 362, 366, 632, 634, 636 and 640, the third insulating interlayer 660 may be patterned to expose the second sacrificial pattern 362 by an etching process, and the exposed second sacrificial pattern 362 may be removed to re-form the first hole exposing the upper surface of the first substrate 10.

An oxidation process may be performed on the exposed upper surface of the first substrate 10 to form an oxide layer 360.

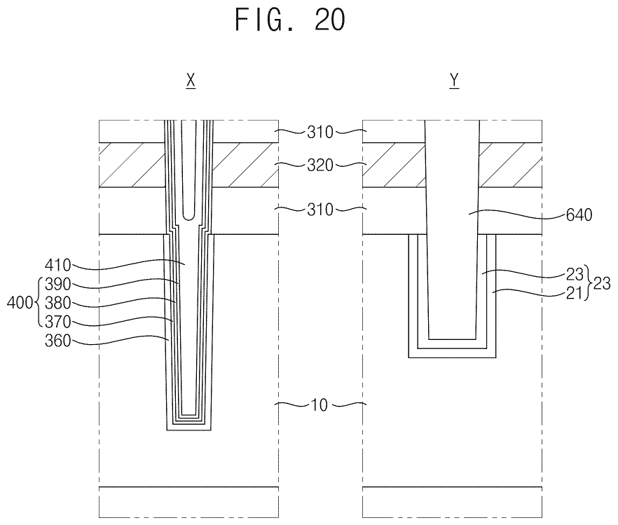

Referring to FIG. 20, a charge storage structure layer 400 may be formed on a surface of the oxide layer 360, a sidewall of the first hole and an upper surface of the third insulating interlayer 660. The charge storage structure layer 400 may include a first blocking layer 370, a charge storage layer 380 and a tunnel insulation layer 390 sequentially stacked.

The first capping layer 410 may be formed, e.g., conformally, on the charge storage structure layer 400. A diameter of a lower portion of the first hole may be smaller than a diameter of an upper portion of the first hole. Accordingly, the lower portion of the first hole may be filled with the first capping layer 410, while the upper portion of the first hole may not be filled with the first capping layer 410 and have an empty space at a center.

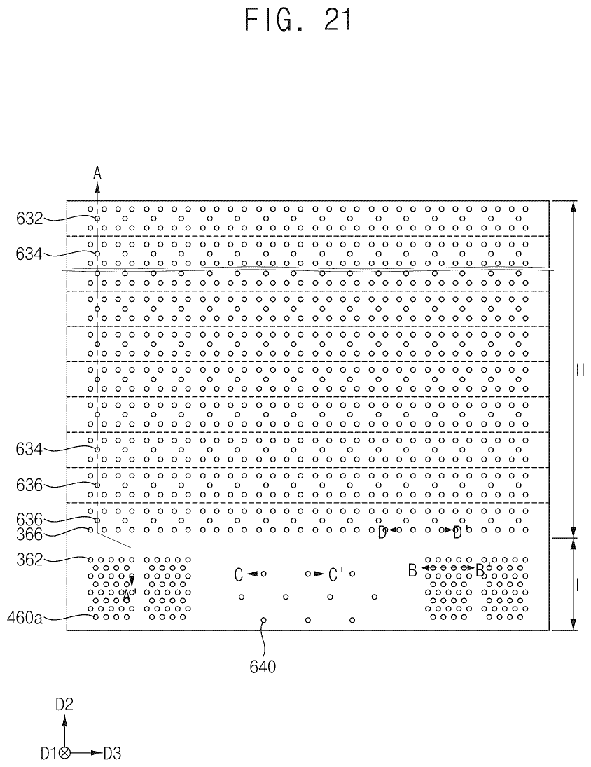

Referring to FIGS. 21 to 23, an etching process may be performed on an upper portion of the first capping layer 410. Compared to a lower portion of the first capping layer 410 partially filling the lower portion of the first hole, a large surface area may be exposed during the etching process. Accordingly, the upper portion of the first capping layer 410 may be removed by the etching process, and the lower portion of the first capping layer 410 may remain. In example embodiments, an upper surface of the first capping layer 410 may be formed to be lower than a lower surface of a lowermost one of the first sacrificial layers 320.

In example embodiments, the etching process may be performed by a wet etching process.

An annealing process may be performed to activate the first capping layer 410.

A channel layer may be formed on the charge storage structure layer 400 and the first capping layer 410, and a filling layer may be formed on the channel layer to fill a remaining portion of the first hole. The filling layer, the channel layer and the charge storage structure layer 400 may be planarized until the upper surface of the third insulating interlayer 660 is exposed. Thus, an oxide layer 360. a charge storage structure 402, a first capping layer 410, a channel 422 and a filling pattern 442 may be formed in the first hole. The charge storage structure 402 may include a first blocking pattern 372, a charge storage pattern 382 and a tunnel insulation pattern 392 sequentially stacked.

Upper portions of the filling pattern 442 and the channel 422 may be removed to form a first recess, and a second capping pattern 452 may be formed to fill the first recess.

The charge storage structure 402, the first capping layer 410, the channel 422, the filling pattern 442 and the second capping pattern 452 in the first hole may collectively form a preliminary memory channel structure 460a.

In example embodiments, the preliminary memory channel structure 460a may have a pillar shape extending in the first direction D1. In example embodiments, a plurality of preliminary memory channel structures 460a may be spaced apart from each other in the second and third directions D2 and D3 on the first region I of the first substrate 10.

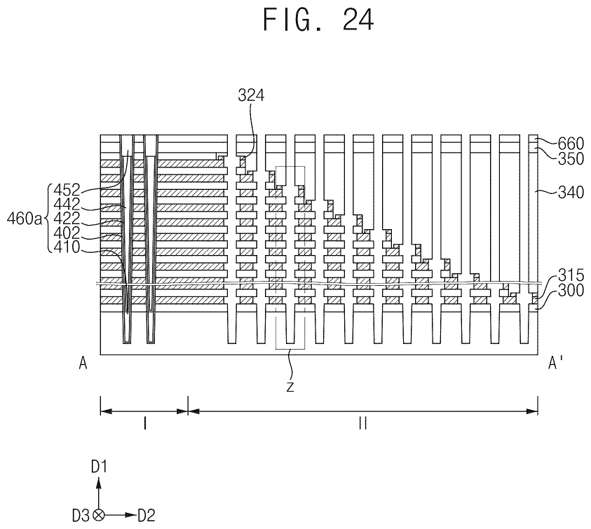

Referring to FIGS. 24 to 26, the third insulating interlayer 660 may be patterned to expose the third to sixth sacrificial patterns 366, 632, 634 and 636 by an etching process, and the third to sixth sacrificial patterns 366, 632, 634 and 636 may be removed to form the second to fifth holes again exposing the upper surface of first substrate 10.

An additional etching process may be performed on portions of the first sacrificial layers 320 adjacent to each of the second to fifth holes to form second and third recesses 672 and 674.

In example embodiments, during the formation of the second recess 672, not only the first sacrificial layer 320 but also the second insulation pad 324, which may be formed on the first sacrificial layer 320 and include substantially the same material as the first sacrificial layer 320, may be removed, and thus, a width in the horizontal direction of the second recess 672 may be formed to be greater than a width in the horizontal direction of the third recess 674.

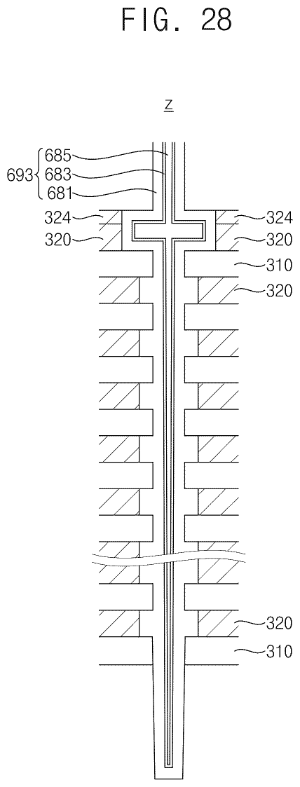

Referring to FIGS. 27 to 29, a second insulation layer may be formed on inner walls of the second to fifth holes and the second and third recesses 672 and 674, and the upper surface of the third insulating interlayer 660 to fill the second and third recesses 672 and 674, a sacrificial liner layer may be formed on the second insulation layer, a second sacrificial layer may be formed on the sacrificial liner layer to fill a remaining portion of the second to fifth holes, and the second sacrificial layer, the sacrificial liner layer and the second insulation layer may be planarized until the upper surface of the third insulating interlayer 660 is exposed.

In example embodiments, the second insulation layer may include an oxide, e.g., silicon oxide, and the sacrificial liner layer may include an insulating nitride, e.g., silicon nitride, and the second sacrificial layer may include, e.g., polysilicon.

By the planarization process, a sacrificial pillar including a second insulation pattern 681, a sacrificial liner 683 and an eighth sacrificial pattern 685 may be formed in each of the second to fifth holes. Specifically, a first sacrificial pillar and second to fourth sacrificial pillars 691, 693 and 695 may be formed in the second to fifth holes, respectively.

After removing the sacrificial liner 683 and the eighth sacrificial pattern 685 included in the first sacrificial pillar, a third insulation pattern may be formed to fill a remaining portion of the second hole. The third insulation pattern may include substantially the same material as the second insulation pattern 681, e.g., oxide such as silicon oxide, and may be merged with the second insulation pattern 681.

Hereinafter, the second insulation pattern 681 and the third insulation pattern in the second hole may be collectively referred to as a support structure 688.

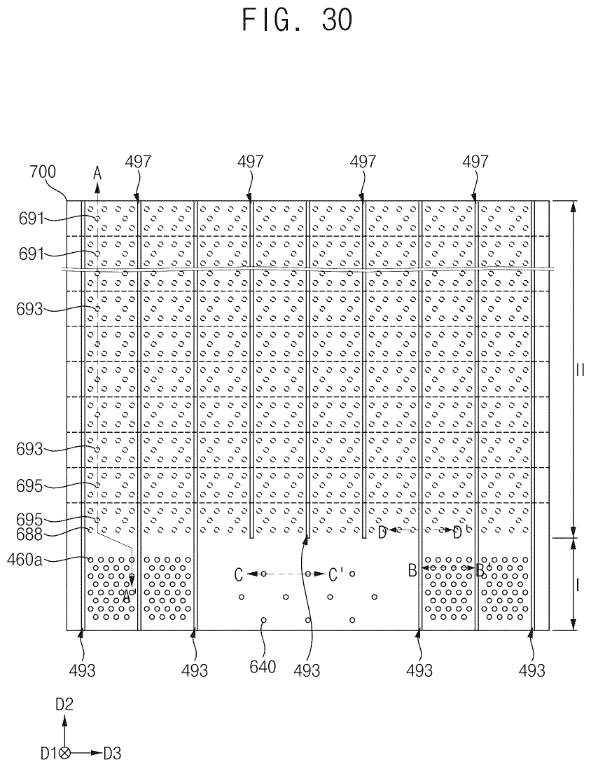

Referring to FIG. 30, a fourth insulating interlayer 700 may be formed on the third insulating interlayer 660, the preliminary memory channel structure 460a, the support structure 688 and the second to fourth sacrificial pillars 691, 693 and 695, and an etching process may be performed to form a first opening 493 extending in the second direction D2 through the first to fourth insulating interlayers 340, 350, 660 and 700, the mold and an upper portion of the first substrate 10 on the first and second regions I and II of the first substrate 10.

In example embodiments, the first opening 493 may extend in the second direction D2 on the first and second regions I and II of the first substrate 10 to both opposite ends in the second direction D2 of the mold having a staircase shape, and a plurality of first openings 493 may be spaced apart from each other in the third direction D3. Accordingly, the mold may be divided into a plurality of parts spaced apart from each other in the third direction D3 by the first openings 493, and each of the molds may form an active memory block or a dummy memory block. By the formation of the first opening 493, the first insulation layers 310 and the first sacrificial layers 320 included in the mold may be divided into a plurality of first insulation patterns 315 and a plurality of first sacrificial patterns 325, respectively, and each of the first insulation patterns 315 and each of the first sacrificial patterns 325 may extend in the second direction D2.

A portion of the first region I of the third substrate 30 on which the active memory block is formed may be referred to as an active memory block region, and a portion of the first region I of the third substrate 30 on which the dummy memory block is formed may be referred to as a dummy memory block region.

A second opening 497 may be formed to extend in the second direction D2 through the first to fourth insulating interlayers 340, 350, 660 and 700, the mold and an upper portion of the first substrate 10 on the first and second regions I and II of the first substrate 10.

In example embodiments, the first and second openings 493 and 497 may not be formed on the dummy memory block region.

Even though the mold is divided into a plurality of parts, each of which may extend in the second direction D2 and spaced apart from each other in the third direction D3 by the wet etching process for forming the first and second openings 493 and 497, the mold may not collapse due to the preliminary memory channel structures 460a, the support structures 688, the second to fourth sacrificial pillars 691, 693 and 695 and the seventh sacrificial pattern 640 extending through the mold.

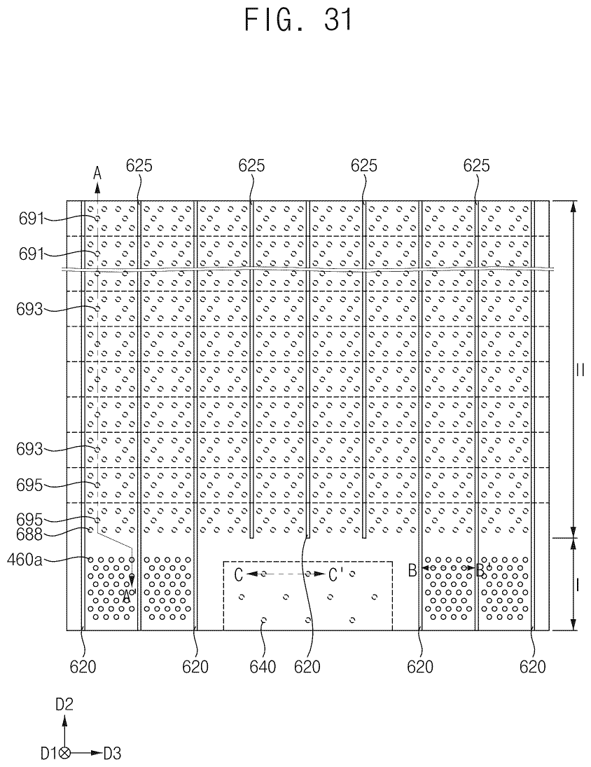

Referring to FIGS. 31 and 34, the first sacrificial pattern 325 and the second insulation pad 324 exposed by the first and second openings 493 and 497 may be removed to form a first gap between neighboring ones of the first insulation patterns 315 in the first direction D1, and a portion of an outer sidewall of the charge storage structure 402 included in the preliminary memory channel structure 460a, a portion of a sidewall of the support structure 688, and a portion of a sidewall of each of the second to fourth sacrificial pillars 691, 693 and 695 may be exposed by the first gap.

In example embodiments, a wet etching process may be performed using, e.g., phosphoric acid (H₃PO₄) or sulfuric acid (H₂SO₄) to remove the first sacrificial patterns 325.

The wet etching process may be performed through the first and second openings 493 and 497, and a portion of the first sacrificial pattern 325 between the first and second openings 493 and 497 may be removed by an etching solution provided from the first and second openings 493 and 497 in both directions, respectively.

However, the first and second openings 493 and 497 may not be formed within the dummy memory block region. Thus, in the dummy memory block region, the etching solution may be provided from only one side of each of the first and second openings 493 and 497 adjacent to the dummy memory block region. Accordingly, the first sacrificial pattern 325 may not be completely removed and partially remain on the dummy memory block region, and the remaining portion of the first sacrificial pattern 325 may be referred to as a fifth insulation pattern 327. A portion of the first insulation pattern 315 that may overlap the fifth insulation patterns 327 in the first direction D1 may be referred to as a fourth insulation pattern 317. The fourth and fifth insulation patterns 317 and 327 alternately and repeatedly stacked in the first direction D1 may collectively form an insulation pattern structure 600.

The insulation pattern structure 600 may extend through a portion of the mold on the dummy memory region of the first substrate 10, and may have a shape of, e.g., a rectangle, an oval, a circle, etc., in a plan view.

A second blocking layer may be formed on the outer sidewall of the charge storage structure 402, the sidewall of the support structure 688 and the sidewall of each of the second to fourth sacrificial pillars 691, 693 and 695 exposed by the first gaps, an inner wall of each of the first gaps 590, surfaces of the first insulation patterns 315, sidewalls of the second to fourth insulating interlayers 350, 660 and 700 and an upper surface of the fourth insulating interlayer 700, and gate electrode layer may be formed on the second blocking layer.

The gate electrode layer may be partially removed to form a gate electrode in each of the first gaps. In example embodiments, the gate electrode layer may be partially removed by a wet etching process. As a result, the first sacrificial pattern 325 of the mold may be replaced with the gate electrode and the second blocking layer covering lower and upper surfaces of the gate electrode.

In example embodiments, the gate electrode may extend in the second direction D2, and a plurality of gate electrodes may be respectively disposed at a plurality of levels spaced apart from each other in the first direction D1 to form a gate electrode structure. The gate electrode structure may have a staircase shape including the gate electrode as a step layer. An end portion in the second direction D2 of each of the gate electrodes, that is, a portion corresponding to a step of a step layer of each of the gate electrodes having a relatively greater thickness, may be referred to as a pad.

In example embodiments, a plurality of gate electrode structures may be spaced apart from each other by the first and second openings 493 and 497 in the third direction D3.

The gate electrode structure may include first to third gate electrodes 751, 753 and 755 sequentially formed along the first direction D1.

A second division layer may be formed on the second blocking layer to fill the first and second openings 493 and 497, and may be planarized until the upper surface of the fourth insulating interlayer 700 is exposed.

Accordingly, the second blocking layer may be transformed into a second blocking pattern 615, and first and second division patterns 620 and 625 may be formed in the first and second openings 493 and 497, respectively.

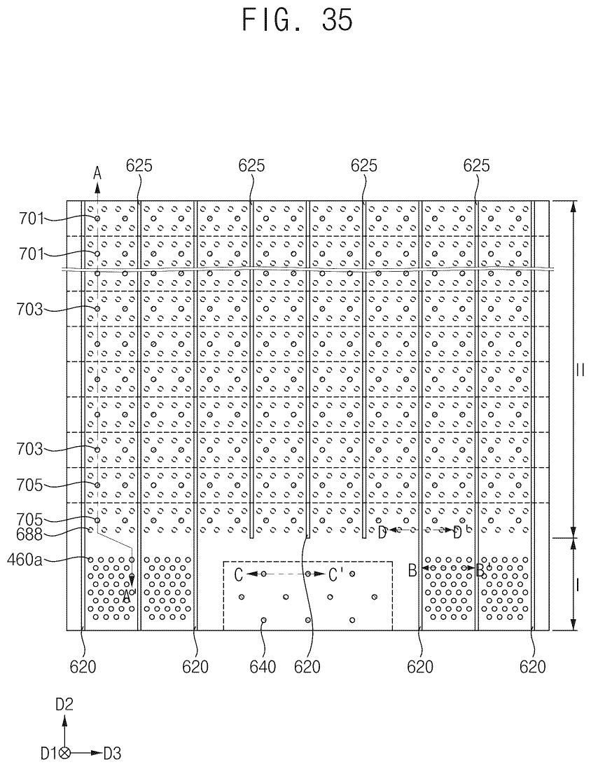

Referring to FIGS. 35 to 37, a planarization process may be performed on the fourth insulating interlayer 700 until the upper surface of the third insulating interlayer 660 is exposed, and upper portions of the first and second division patterns 620 and 625 may also be removed by the planarization process. Thus, upper surfaces of the preliminary memory channel structure 460a and the second to fourth sacrificial pillars 691, 693 and 695 may be exposed.

The exposed second to fourth sacrificial pillars 691, 693 and 695 may be partially removed to re-form the third to fifth holes, respectively.

Specifically, the eighth sacrificial pattern 685 and the sacrificial liner 683 included in each of the second to fourth sacrificial pillars 691, 693 and 695 may be removed. A portion of the second insulation pattern 681 formed in the second recess 672 having a relatively large width in the first direction D1 may be removed, while a portion of the second insulation pattern 681 formed in the third recess 674 having a relatively small width in the first direction D1 may remain to form a fourth insulation pattern 686.

A portion of the second blocking pattern 615 exposed by the second recess 672 may be removed, thereby exposing a sidewall of an uppermost one of the gate electrodes penetrated by each of the third to fifth holes.

First to third upper contact plugs 701, 703 and 705 may be formed in the third to fifth holes, respectively.

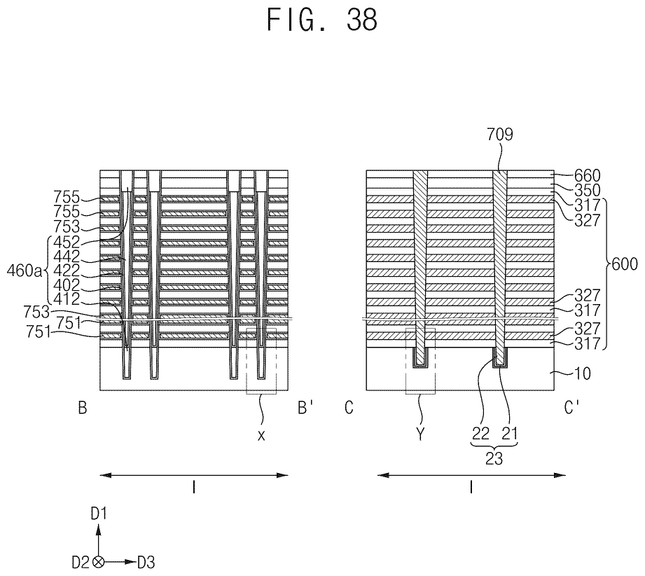

Referring to FIG. 38, the third insulating interlayer 660 may be patterned to expose the seventh sacrificial pattern 640. The exposed seventh sacrificial pattern 640 may be removed to re-form the sixth hole, and accordingly, the upper surface of the landing pad 22 may be exposed.

A through via 709 contacting the landing pad 22 may be formed within the sixth hole.

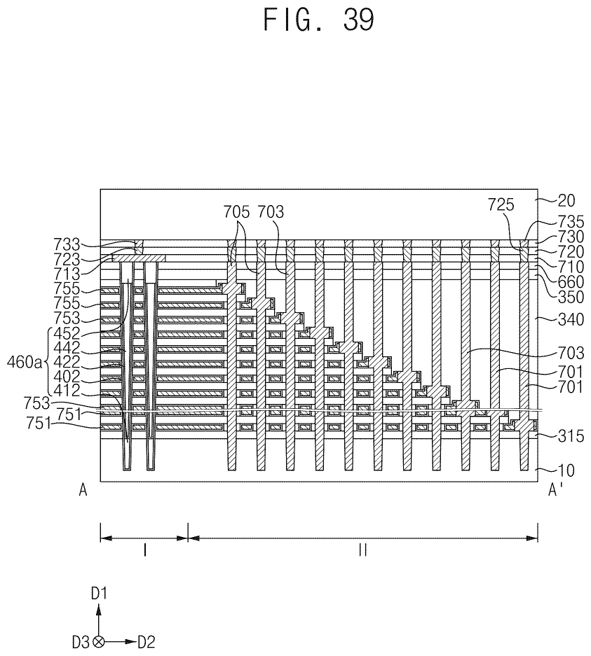

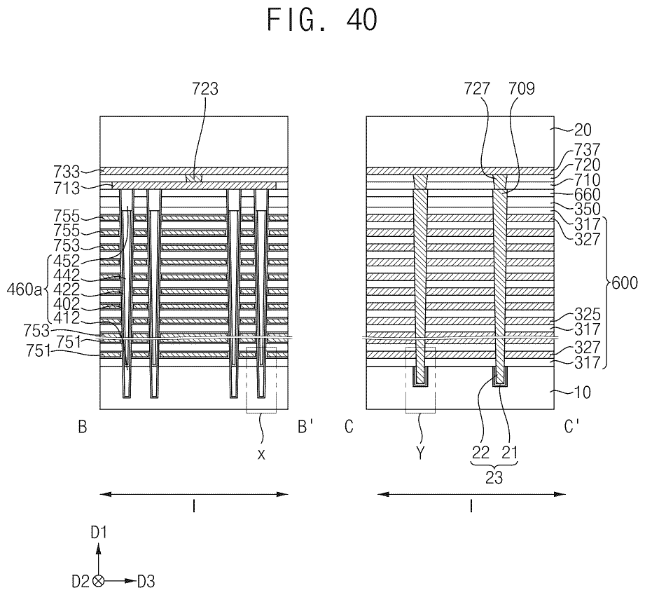

Referring to FIGS. 39 and 40, a fifth insulating interlayer 710 may be formed on the preliminary memory channel structure 460a, the first to third upper contact plugs 701, 703 and 705, the through via 709 and the third insulating interlayer 660.

A common source plate (CSP) 713 may be formed to extend through the fifth insulating interlayer 710 and contact the upper surface of the preliminary memory channel structure 460a.

In example embodiments, the CSP 713 may commonly contact the upper surfaces of the preliminary memory channel structures 460a of the active memory block, and accordingly, the preliminary memory channel structures 460a of the active memory block may be electrically connected to each other. In example embodiments, a plurality of CSPs 713 may be formed to be spaced apart from each other in the third direction D3 corresponding to the active memory blocks.

A sixth insulating interlayer 720 may be formed on the CSP 713 and the fifth insulating interlayer 710. A first via 723 may be formed through the sixth insulating interlayer 720 to contact the upper surface of the CSP 713. A second via 725 may be formed through the fifth and sixth insulating interlayer 710 and 720 to contact the upper surfaces of the first to third upper contact plugs 701, 703 and 705, respectively. A third via 727 may be formed through the fifth and sixth insulating interlayer 710 and 720 to contact the upper surface of the through via 709.

A seventh insulating interlayer 730 may be formed on the first to third vias 723, 725 and 727 and the sixth insulating interlayer 720. First to third wirings 733, 735 and 737 may be formed through the fifth insulating interlayer 710 to contact upper surfaces of the first to third vias 723, 725 and 727, respectively.

In example embodiments, each of the first and third wirings 733 and 737 may extend in the third direction D3.

A second substrate 20 may be formed on the first to third wirings 733, 735 and 737 and the seventh insulating interlayer 730.

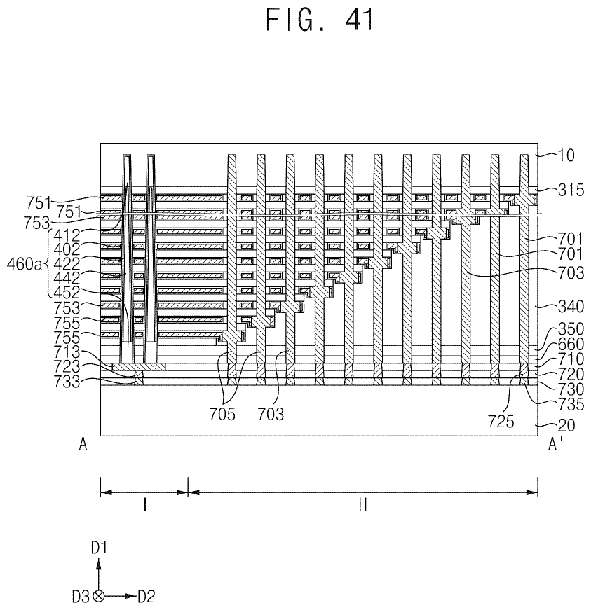

Referring to FIGS. 41 to 43, various structures formed on the first substrate 10 may be turned over using the second substrate 20.

Hereinafter, the following description may be based on a state in which top and bottom of the structures on the first substrate 10 are inverted.

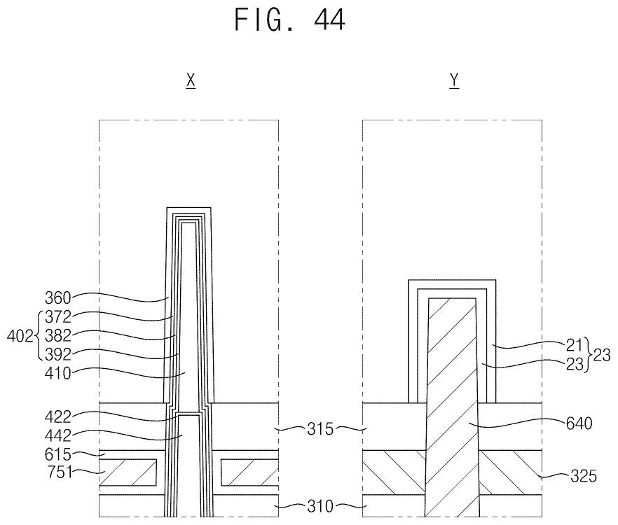

Referring to FIG. 44, the first substrate 10 may be removed. Accordingly, an upper surface of the first insulation pattern 315, an upper surface and an outer sidewall of the oxide layer 360 and an upper surface and an outer sidewall of the buffer pattern 21 may be exposed.

In example embodiments, the first substrate 10 may be removed by a wet etching process.

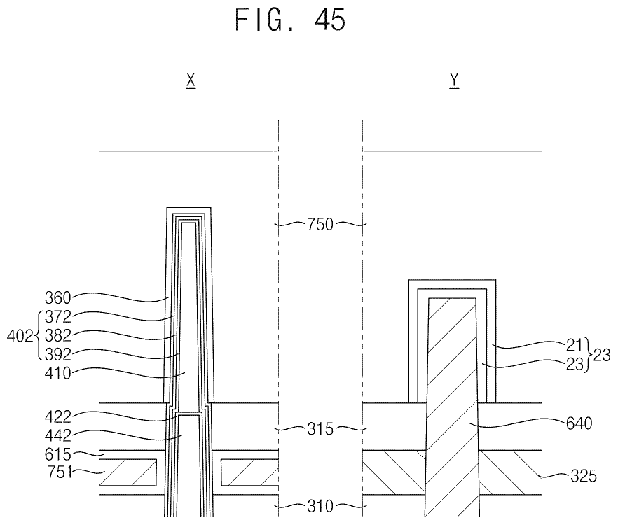

Referring to FIG. 45, an eighth insulating interlayer 750 may be formed at a sufficient height on the upper surface of the first insulation pattern 315, the upper surface and the outer sidewall of the oxide layer 360 and the upper surface and the outer sidewall of the buffer pattern 21.

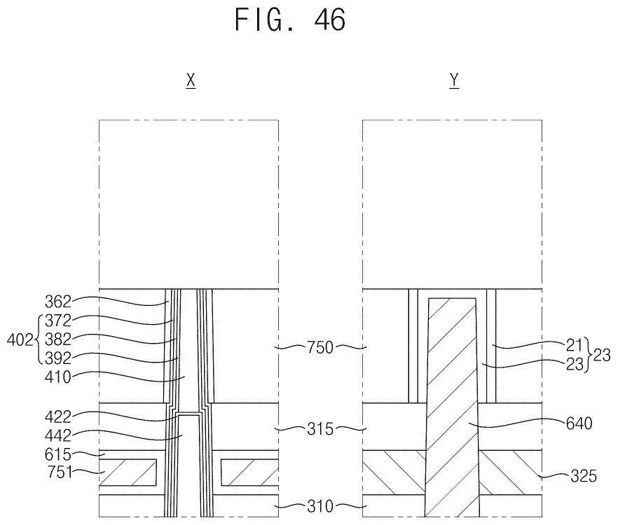

Referring to FIG. 46, a planarization process may be performed until the upper surface of the landing structure 23 may be exposed. Accordingly, upper portions of the oxide layer 360, the charge storage structure 402 and the first capping layer 410 may be removed.

The oxide layer 360 may be transformed to an oxide pattern 362, the first capping layer 410 may be transformed to a first capping pattern 412 and the preliminary memory channel structure 460a may be transformed to a memory channel structure 460 including the storage structure 402, the first capping pattern 412, the channel 422, the filling pattern 442 and the second capping pattern 452.

Upper surfaces of the first blocking pattern 372, the charge storage pattern 382 and the tunnel insulation pattern 392 of the charge storage structure 402 and the upper surface of the landing structure 23 may be exposed by the planarization process.

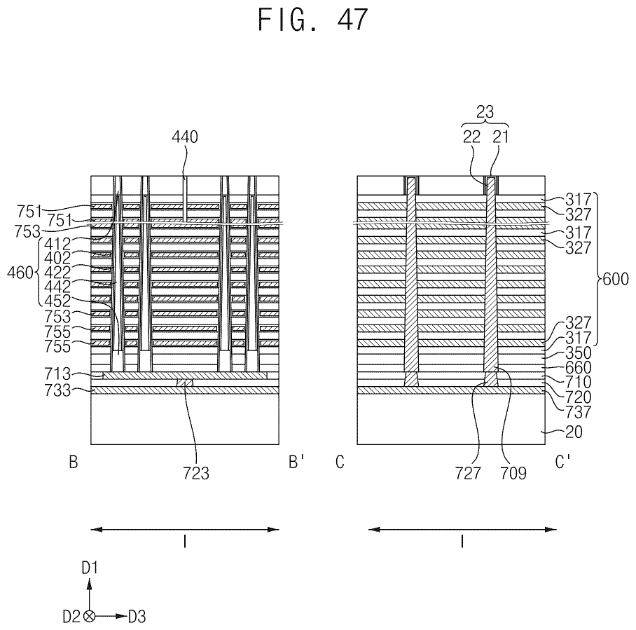

Referring to FIG. 47, a third opening may be formed by etching the eighth insulating interlayer 750, a portion of the first insulation pattern 315, a portion of the second blocking pattern 615 and the first gate electrode 751, and a third division pattern 440 may be formed to fill the third opening.

In example embodiments, the third division pattern 440 may partially extend through an upper portion of the memory channel structure 460. The third division pattern 440 may not only extend through the upper portion of the memory channel structure 460, but also the first gate electrodes 751 formed at upper two layers, the first insulation patterns 315 formed at the upper two layers, and a portion of the first insulation pattern 315 at a layer below the upper two layers. The third division pattern 440 may extend in the second direction D2 on the first and second regions I and II of the first substrate 10 through upper two step layers of the gate electrode structure. Accordingly, each of the first gate electrodes 751 at the upper two step layers may be separated in the third direction D3 by the third division pattern 440.

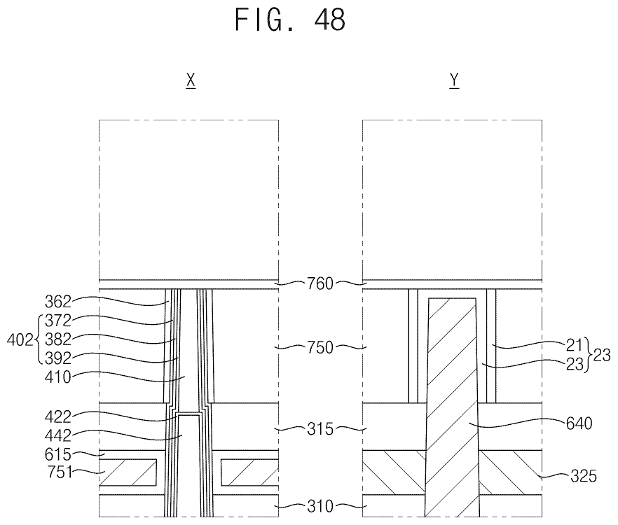

Referring to FIG. 48, an etch stop layer 760 may be formed on the upper surfaces of the first blocking pattern 372, the charge storage pattern 382 and the tunnel insulation pattern 392 of the charge storage structure 402, the upper surface of the landing structure 23, an upper surface of the oxide pattern 362, an upper surface of the third division pattern 440 and the upper surface of the eighth insulating interlayer 750.

In example embodiments, the etch stop layer 760 may include a material having an etching selectivity with respect to a ninth insulating interlayer 790 which is formed later.

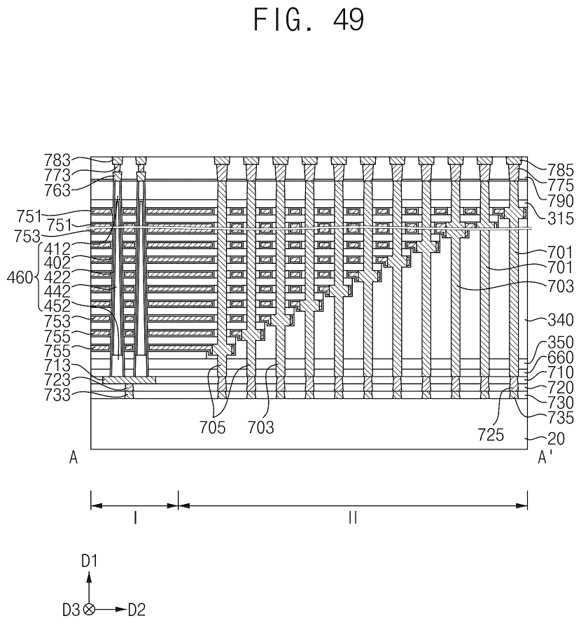

Referring to FIGS. 49 to 51, a fourth via 763, a fifth via 773 and a fourth wiring 783 may be sequentially formed on the memory channel structure 460. The fourth wiring 783 may extend in the third direction D3 and a plurality of fourth wirings 783 may be spaced apart from each other in the second direction D2. The fourth wiring 783 may serve as a bit line. A sixth via 775 and a fifth wiring 785 may be sequentially formed on each of the first to third upper contact plugs 701, 703 and 705. A seventh via 767, an eighth via 777 and a sixth wiring 787 may be sequentially formed on the through via 709.

The ninth insulating interlayer 790 may cover the fourth to eighth vias 763, 773, 775, 767 and 777 and the fourth to sixth wirings 783, 785 and 787.

In example embodiments, a width in the horizontal direction of a lower surface of the fourth via 763 may be greater than a width in the horizontal direction of an upper surface of the first capping pattern 412 of the memory channel structure 460. A width of the memory channel structure 460 may become smaller from bottom to top. If the fifth via 773, which electrically connects the fourth wiring 783 serving as a bit line and the memory channel structure 460, is directly formed on the upper surface of the memory channel structure 460 having a relatively small width, misalignment may increase. However, in example embodiments, the fourth via 773 having a relatively large width, may be directly formed on the memory channel structure 460, and thus, misalignment may decrease.

If the fifth via 773 is formed to directly contact the memory channel structure 460 instead of the fourth via 763, a width in the horizontal direction of a lower surface of the fifth via 773 may be greater than the width in the horizontal direction of the upper surface of the first capping pattern 412.

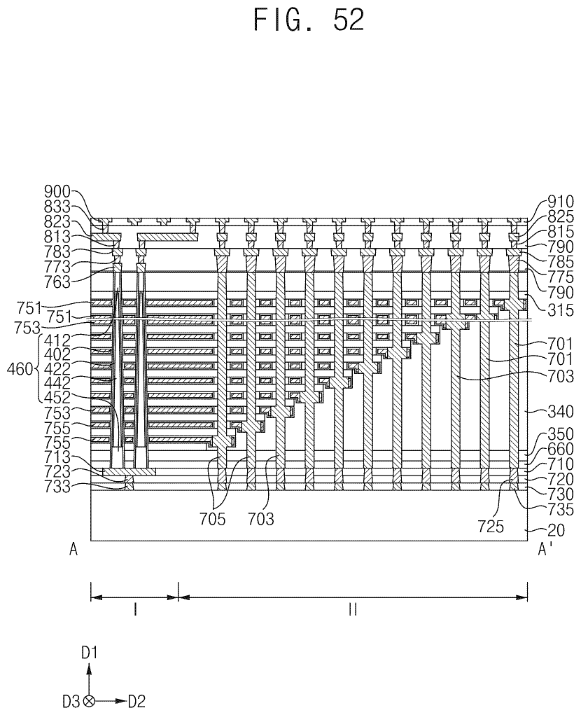

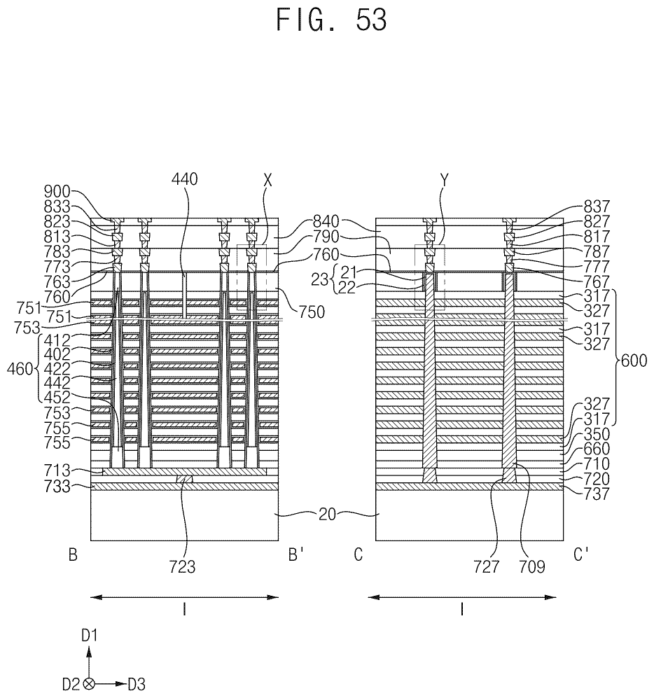

Referring to FIGS. 52 and 53, the ninth via 813, the seventh wiring 823 and the tenth via 833 may be sequentially formed on the fourth wiring 783. The seventh wiring 823 may handle the routing of the fourth wirings 783 serving as the bit line. An eleventh via 815, an eighth wiring 825 and a twelfth via 835 may be sequentially formed on the fifth wiring 785. A thirteenth via 817, a ninth wiring 827 and a fourteenth via 837 may be sequentially formed on the sixth wiring 787.

The tenth insulating interlayer 840 may cover the ninth to fourteenth vias 813, 833, 815, 835, 817 and 837 and the seventh to tenth wirings 823, 825 and 827.

Hereinafter, for convenience of explanation, various structures formed on the second substrate 20 may collectively be referred to as a first structure.

A first bonding pattern 900 in contact with one of the eighth to tenth wirings 823, 825 and 827 and a first bonding layer 910 covering the first bonding pattern 900 may be formed on the first structure. In example embodiments, a plurality of first bonding patterns 900 may be formed to be spaced apart from each other in the second and third directions D2 and D3.

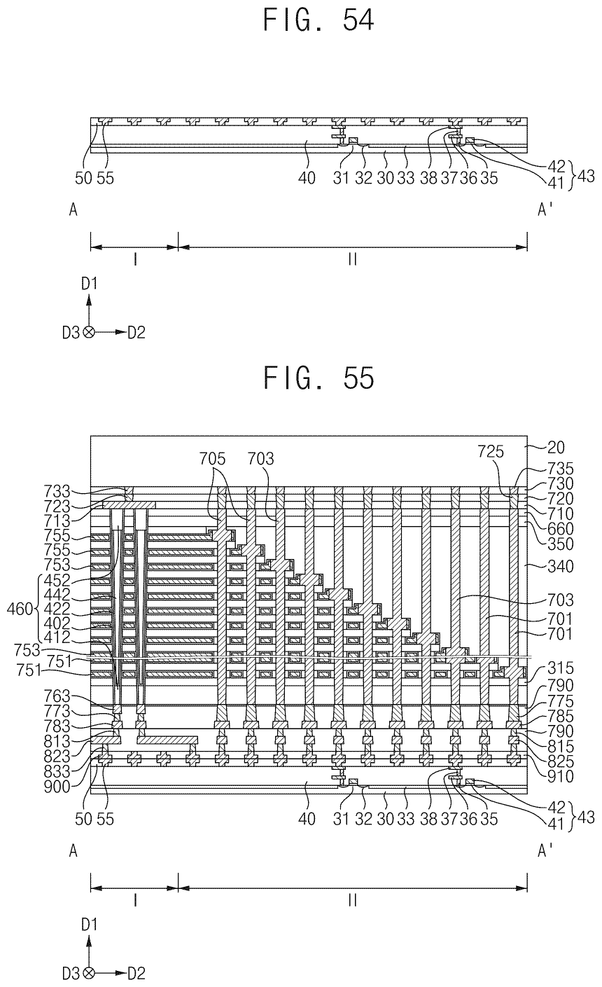

Referring to FIG. 54, a lower circuit pattern and an eleventh insulating interlayer 40 covering the lower circuit pattern may be formed on a third substrate 30.

The third substrate 30 may include a first region I and a second region II surrounding the first region I, corresponding to the first substrate 10.

The lower circuit pattern may include, e.g., a transistor, a lower contact plug 35, first and second lower wirings 36 and 38 and a lower via 37. Each component constituting the lower circuit pattern may be formed by an engraved patterning method or a damascene process.

The transistor, for example, may include a lower gate structure 43 disposed on the third substrate 30, and an impurity region 32 that may be disposed on an upper portion of the active region 31 adjacent to the lower gate structure 43 and serve as a source/drain.

The lower gate structure 43 may include a lower gate insulation pattern 41 and a lower gate electrode 42 sequentially stacked on the third substrate 30. The lower contact plug 35 may contact the impurity region 32. A lower contact plug contacting the lower gate electrode 42 may be additionally formed. A first lower wiring 36, a lower via 37 and a second lower wiring 38 may be sequentially formed on the lower contact plug 35. A second bonding pattern 55 and a second bonding layer 50 covering the second bonding pattern 55 may be formed on the eleventh insulating interlayer 40 and the lower circuit pattern.

In example embodiments, a plurality of second bonding patterns 55 may be formed to be spaced apart from each other in the second and third directions D2 and D3. The second bonding patterns 55 may be formed at positions corresponding to the first bonding patterns 900.

Referring to FIG. 55, the second substrate 20 may be turned over and the first bonding layer 910 may be bonded to the second bonding layer 50, and the first bonding patterns 900 may be bonded to the second bonding patterns 55, respectively. The first and second bonding patterns 900 and 55 and the first and second bonding layers 910 and 50 may collectively form a first bonding structure.

Referring to FIGS. 1 to 4 again, manufacturing of the integrated circuit semiconductor device may be completed by removing the second substrate 20.

As illustrated above, the first hole may be formed to extend through the mold on the first substrate 10, a first capping layer 410 may be formed at the lower portion of the first hole, and the annealing process may be performed to activate the first capping layer 410. The structures on the first substrate 10 may be reversed, and the first bonding patterns 900 may be formed on the reversed structures on the first substrate 10. The second bonding patterns 55 may be formed on the lower circuit pattern on the third substrate 30, and the structures on the first substrate 10 may be reversed again to be bonded to the lower circuit pattern on the third substrate.

There may be a limit in performing the annealing process sufficiently on the first capping layer 410 after forming the first and second bonding patterns 900 and 55 including, e.g., copper. However, in the method of manufacturing the integrated circuit semiconductor device, the first bonding pattern 900 may be formed after performing the annealing process on the first capping layer 410, and thus, the annealing process may be performed sufficiently.

Additionally, the CSP 713 connecting the memory channel structures 460 of the active memory block to each other may be formed over the memory channel structures 460. Accordingly, overall process complexity may be reduced compared to when forming the CSP 713 to contact lower sidewalls of the memory channel structures 460.

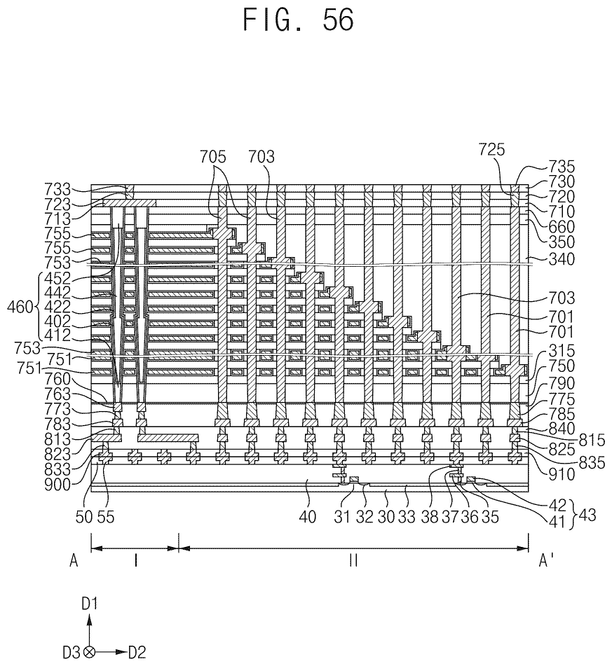

FIG. 56 is a cross-sectional view illustrating an integrated circuit semiconductor device in accordance with example embodiments, which may correspond to FIG. 3. This semiconductor device may be substantially the same as or similar to that of FIGS. 1 to 5, except for the shape of the memory channel structure 460.

Referring to FIG. 56, the memory channel structure 460 may include lower and upper portions sequentially stacked in the first direction D1, and each of the lower and upper portions may have a width gradually decreasing from a top toward a bottom thereof. In example embodiments, an upper surface of the lower portion of the memory channel structure 460 may have a width greater than a lower surface of the upper portion of the memory channel structure 460.

FIG. 56 shows that the memory channel structure 460 includes two portions stacked in the first direction D1, however, the inventive concept may not be limited thereto, and may include more than two portions stacked in the first direction D1. Each of the portions of the memory channel structure 460 may have a width gradually decreasing from a top toward a bottom thereof, and an upper surface of a portion of the memory channel structure 460 may have a width greater than a lower surface of a portion of the memory channel structure 460 thereon.

The support structure 688 may have a shape similar to that of the memory channel structure 460. That is, the support structure 688 may include a plurality of portions sequentially stacked in the first direction D1, and each of the portions may have a width gradually decreasing from a top toward a bottom thereof.

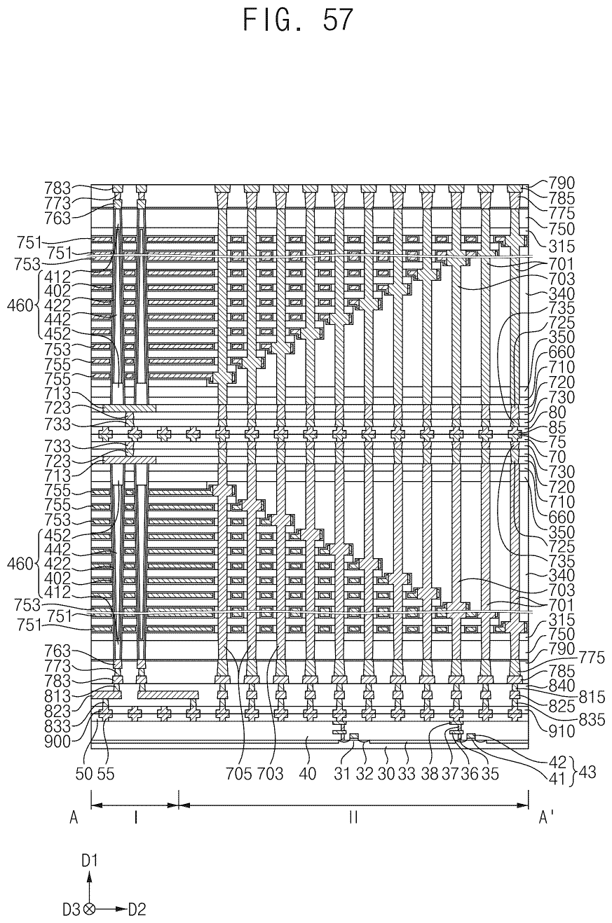

FIG. 57 is a cross-sectional view illustrating an integrated circuit semiconductor device in accordance with example embodiments, which may correspond to FIG. 3. This semiconductor device may be substantially the same as or similar to that of FIGS. 1 to 5, except for including a second structure corresponding to the first structure and a second bonding structure, and thus repeated explanations are omitted herein.

Referring to FIG. 57, the second bonding structure may include third and fourth bonding patterns 75 and 85 and third and fourth bonding layers 70 and 80.

The third bonding layer 70 may be formed on the first structure, and the third bonding pattern 75 may extend through the third bonding layer 70 to contact one of the wirings or vias of the first structure. In example embodiments, a plurality of third bonding patterns 75 may be formed to be spaced apart from each other in the second and third directions D2 and D3.

The third bonding pattern 75 and the third bonding layer 70 may be substantially the same as or similar to the second bonding pattern 55 and the second bonding layer 50, respectively.

The fourth bonding layer 80 may be formed on the third bonding layer 70, and the fourth bonding pattern 85 may extend through the fourth bonding layer 80 to contact a corresponding one of the third bonding patterns 75. In example embodiments, a plurality of fourth bonding patterns 85 may be formed to be spaced apart from each other in the second and third directions D2 and D3 corresponding to the third bonding patterns 75.

In example embodiments, the fourth bonding pattern 85 and the fourth bonding layer 80 may be substantially the same as or similar to the first bonding pattern 900 and the first bonding layer 910, respectively.

The second structure may be formed on the second bonding structure. The second structure may be substantially the same as or similar to the first structure but reversed. The first and second structures may be electrically connected to each other by the third and fourth bonding patterns 75 and 85. Compared to the first structure, the second structure may not include the ninth to fourteenth vias 813, 833, 815, 835, 817 and 837, the seventh to ninth wirings 823, 825 and 827 and the tenth insulating interlayer 840.

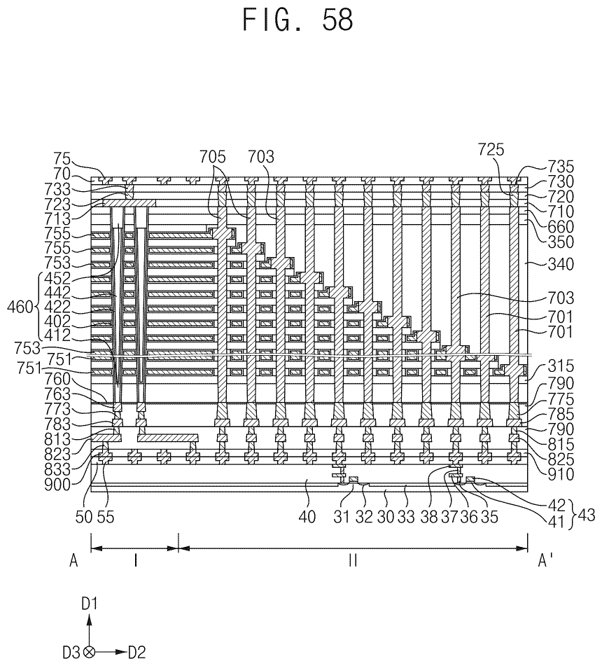

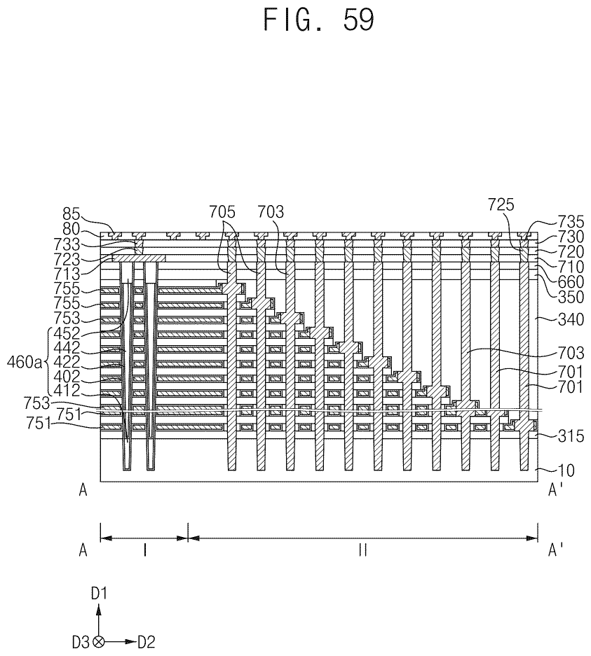

FIGS. 58 to 59 are cross-sectional views illustrating a method of forming an integrated circuit semiconductor device in accordance with example embodiments. This method may include processes substantially the same as or similar to those illustrated with reference to FIGS. 1 to 54, and thus repeated explanations thereof are omitted herein.

Referring to FIG. 58, the first structure may be formed by performing the processes illustrated with reference to FIGS. 1 to 54, and a third bonding layer 70 and a third bonding pattern 75 extending through the third bonding layer 70 to contact one of the wirings or the vias of the first structure may be formed on the first structure.

Referring to FIG. 59, the processes illustrated with reference to FIGS. 6 to 40 may be performed. Hereinafter, for convenience of explanation, the first substrate 10 and the structures formed on the first substrate 10 (e.g., the preliminary memory channel structure 460a) may be collectively referred to as a preliminary second structure. However, unlike the processes illustrated with reference to FIGS. 39 and 40, instead of forming the second substrate 20 on the preliminary second structure, a fourth bonding layer 80 and a fourth bonding pattern 85 extending through the fourth bonding layer 80 to contact one of wirings or vias of the preliminary second structure may be formed. The fourth bonding pattern 85 may be formed at a position corresponding to the third bonding pattern 75.

Referring to FIG. 57 again, the preliminary second structure may be turned over and the fourth bonding layer 80 may be bonded to the third bonding layer 70, and each of the fourth bonding patterns 85 may contact a corresponding one of the third bonding patterns 75. The third and fourth bonding patterns 75 and 85 and the third and fourth bonding layers 70 and 80 may collectively form a second bonding structure.

The preliminary memory channel structure 460a of the preliminary second structure may be transformed into the memory channel structure 460 by performing the processes illustrated with reference to FIGS. 41 to 51. Accordingly, the preliminary second structure may be transformed into the second structure corresponding to the first structure, and manufacturing of the integrated circuit semiconductor device may be completed.

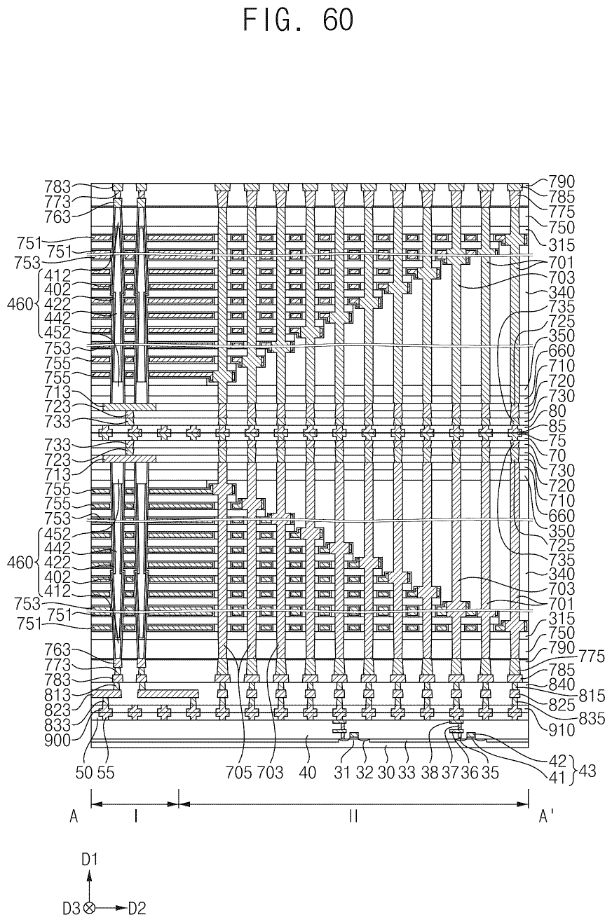

FIG. 60 is a cross-sectional view illustrating an integrated circuit semiconductor device in accordance with example embodiments, which may correspond to FIG. 57. This semiconductor device may be substantially the same as or similar to that of FIG. 57, except for the shape of the memory channel structures 460 of the first and second structures, respectively, and thus repeated explanations are omitted herein.

Referring to FIG. 60, the memory channel structure 460 of the first structure may include lower and upper portions sequentially stacked in the first direction D1, and each of the lower and upper portions may have a width gradually decreasing from a top toward a bottom thereof. In example embodiments, an upper surface of the lower portion of the memory channel structure 460 may have a width greater than a lower surface of the upper portion of the memory channel structure 460.

The memory channel structure 460 of the second structure may include lower and upper portions sequentially stacked in the first direction D1, and each of the lower and upper portions may have a width gradually increasing from a top toward a bottom thereof. In example embodiments, an upper surface of the lower portion of the memory channel structure 460 may have a width smaller than a lower surface of the upper portion of the memory channel structure 460.

FIG. 60 shows that the memory channel structure 460 of the first structure includes two portions stacked in the first direction D1, however, the inventive concept may not be limited thereto, and may include more than two portions stacked in the first direction D1. Each of the portions of the memory channel structure 460 may have a width gradually decreasing from a top toward a bottom thereof, and an upper surface of a portion of the memory channel structure 460 may have a width greater than a lower surface of a portion of the memory channel structure 460 thereon.

The support structure 688 of the first structure may have a shape similar to that of the memory channel structure 460. That is, the support structure 688 may include a plurality of portions sequentially stacked in the first direction D1, and each of the portions may have a width gradually decreasing from a top toward a bottom thereof.

FIG. 60 shows that the memory channel structure 460 of the second structure includes two portions stacked in the first direction D1, however, the inventive concept may not be limited thereto, and may include more than two portions stacked in the first direction D1. Each of the portions of the memory channel structure 460 may have a width gradually increasing from a top toward a bottom thereof, and an upper surface of a portion of the memory channel structure 460 may have a width smaller than a lower surface of a portion of the memory channel structure 460 thereon.

The support structure 688 of the second structure may have a shape similar to that of the memory channel structure 460. That is, the support structure 688 may include a plurality of portions sequentially stacked in the first direction D1, and each of the portions may have a width gradually increasing from a top toward a bottom thereof.

While example embodiments have been particularly shown and described, it will be understood by one of ordinary skill in the art that variations in form and detail may be made therein without departing from the spirit and scope of the claims.

What is claimed is:

1. An integrated circuit device, comprising:
a lower circuit pattern on a substrate;
a bit line on the lower circuit pattern;
a gate electrode structure on the bit line, said gate electrode structure including gate electrodes that are spaced apart from each other in a first direction, and having a length in a second direction that gradually decreases from a bottom to a top along the first direction, which is substantially perpendicular to an upper surface of the substrate, and wherein the second direction is substantially parallel to the upper surface of the substrate;
a memory channel structure extending through the gate electrode structure, said memory channel structure including:
a first capping pattern on the bit line;
a channel on the first capping pattern;
a second capping pattern on the channel; and
a charge storage structure at outer sidewalls of the first capping pattern, the channel and the second capping pattern; and
a common source plate (CSP) on the memory channel structure.

2. The device of claim 1, wherein a width of at least a portion of the memory channel structure increases from a bottom to a top in the first direction.

3. The device of claim 1, further comprising:
a via on the bit line;
wherein a lower surface of the first capping pattern contacts an upper surface of the via; wherein a width in a horizontal direction of the upper surface of the via is greater than a width in the horizontal direction of the lower surface of the first capping pattern; and wherein the horizontal direction is substantially parallel to the upper surface of the substrate.

4. The device of claim 3, wherein a width of the via decreases from a bottom to a top.

5. The device of claim 1, wherein the channel has a shape of a cup.

6. The device of claim 1, further comprising:
a bonding structure on the lower circuit pattern, said bonding structure including a first bonding layer on the lower circuit pattern, a first bonding pattern extending through the first bonding layer, a second bonding layer on the first bonding layer and the first bonding pattern, and a second bonding pattern extending through the second bonding layer to contact the first bonding pattern;
wherein the gate electrode structure extends on the bonding structure; and
wherein each of the first and second bonding patterns includes copper.

7. An integrated circuit device, comprising:
a lower circuit pattern on a substrate;
a gate electrode structure including gate electrodes that are spaced apart from each other in a first direction, said gate electrode structure having a length in a second direction that gradually decreases from a bottom to a top along the first direction, which is substantially perpendicular to an upper surface of the substrate, and wherein the second direction is substantially parallel to the upper surface of the substrate;
an insulation pattern structure extending through the gate electrode structure, said insulation pattern structure including first insulation patterns respectively disposed at heights corresponding to the gate electrodes, and second insulation patterns disposed between neighboring ones in the first direction of the first insulation patterns;
a memory channel structure extending through the gate electrode structure, said memory channel structure including:
a first capping pattern on the bit line;
a channel on the first capping pattern;
a second capping pattern on the channel; and
a charge storage structure at outer sidewalls of the first capping pattern, the channel and the second capping pattern;
a through-via extending through the insulation pattern structure; and
a common source plate (CSP) on the memory channel structure.

8. The device of claim 7, wherein a width of at least a portion of the memory channel structure increases from a bottom to a top in the first direction, and a width of at least a portion of the through via increases from a bottom to a top in the first direction.

9. The device of claim 7, further comprising a landing structure that covers a lower sidewall and a lower surface of the through-via.

10. The device of claim 9, wherein a lower surface of the memory channel structure is substantially coplanar with a lower surface of the landing structure.

11. The device of claim 9, further comprising an etch stop layer on the lower circuit pattern, said etch stop layer having an upper surface that is substantially coplanar with a lower surface of the memory channel structure and a lower surface of the landing structure.

12. The device of claim 9, wherein the landing structure includes a landing pad covering the lower sidewall and the lower surface of the through-via, and a buffer pattern covering an outer sidewall of the landing pad.

13. The device of claim 9, further comprising:
a first via contacting a lower surface of the first capping pattern; and
a second via contacting a lower surface of the landing structure; and
wherein a width in a horizontal direction of an upper surface of the first via is greater than a width in the horizontal direction of the lower surface of the first capping pattern, and the horizontal direction is substantially parallel to the upper surface of the substrate.

14. The device of claim 13, wherein a width of each of the first and second vias decreases from a bottom to a top.

15. The device of claim 7, further comprising:
a bonding structure on the lower circuit pattern, said bonding structure including a first bonding layer on the lower circuit pattern, a first bonding pattern extending through the first bonding layer, a second bonding layer on the first bonding layer and the first bonding pattern, and a second bonding pattern extending through the second bonding layer to contact the first bonding pattern;
wherein the gate electrode structure and the insulation pattern structure extend on the bonding structure; and
wherein each of the first and second bonding patterns includes copper.

16. The device of claim 7, wherein the channel has a shape of a cup.

17. An integrated circuit device, comprising:
a lower circuit pattern on a substrate;
a first bonding structure on the lower circuit pattern;
a first bit line on the first bonding structure;
a first gate electrode structure including first gate electrodes that are spaced apart from each other in a first direction, said first gate electrode structure having a length in a second direction that gradually decreases from a bottom to a top along the first direction, which is substantially perpendicular to an upper surface of the substrate, and wherein the second direction is substantially parallel to the upper surface of the substrate;
a first memory channel structure extending through the first gate electrode structure, said first memory channel structure including a first capping pattern on the first bit line, a first channel on the first capping pattern, a second capping pattern on the first channel and a first charge storage structure at outer sidewalls of the first capping pattern, the first channel and the second capping pattern;
a first common source plate (CSP) on the first memory channel structure;
a second bonding structure on the first CSP;
a second CSP on the second bonding structure;
a second gate electrode structure including second gate electrodes spaced apart from each other in the first direction, said second gate electrode structure having a length in the second direction that increases from a bottom to a top along the first direction;
a second memory channel structure extending through the second gate electrode structure, said second memory channel structure including a third capping pattern, a second channel on the third capping pattern, a fourth capping pattern on the second channel and a second charge storage structure at outer sidewalls of the third capping pattern, the second channel and the fourth capping pattern; and
a second bit line on the second memory channel structure.

18. The device of claim 17, wherein a width of at least a portion of the first memory channel structure increases from a bottom to a top in the first direction, and a width of at least a portion of the second memory channel structure decreases from a bottom to a top in the first direction.

19. The device of claim 17,
wherein the first bonding structure includes a first bonding layer on the lower circuit pattern, a first bonding pattern extending through the first bonding layer, a second bonding layer on the first bonding layer and the first bonding pattern, and a second bonding pattern extending through the second bonding layer to contact the first bonding pattern, and each of the first and second bonding patterns including copper; and
wherein the second bonding structure includes a third bonding layer on the first CSP, a third bonding pattern extending through the third bonding layer, a fourth bonding layer on the third bonding layer and the third bonding pattern, and a fourth bonding pattern extending through the fourth bonding layer to contact the third bonding pattern, and each of the third and fourth bonding patterns including copper.

20. The device of claim 17, wherein the first channel has a shape of a cup, and the second channel has a shape of an upside down cup.
